(19) United States
(12) Patent Application Publication
(10) Pub. No.: US 2026/0176128 A1
(43) Pub. Date: Jun. 25, 2026

(54) MICROMECHANICAL BEAM

(71) Applicants: nano analytik GmbH, Ilmenau (DE); nexensor, Yuseon-gu, Daejeon (KR)

(72) Inventor: Ivo RANGELOW, Baunatal (DE)

(21) Appl. No.: 19/124,637

(22) PCT Filed: Oct. 26, 2023
(86) PCT No.: PCT/EP2023/080013

§ 371 Date: Apr. 25, 2025

(30) Foreign Application Priority Data
Oct. 26, 2022 (GB) 2215845.5

(51) Int. Cl. B81B 3/00

(52) U.S. Cl. CPC B81B 3/0072; B81B 2203/0109

(57) ABSTRACT

A micromechanical beam for scanning probe measurements, lithography and the like, the micromechanical beam extending in a longitudinal direction between a fixed end and a free end. The beam has a height along a height direction perpendicular to the longitudinal direction, the height being smaller than a width along a width direction. Furthermore, the beam has a bending section that is located in the longitudinal direction at the fixed end of the beam and a reinforcement section that is located in the longitudinal direction between the bending section and the free end. In the reinforcement section, the beam has a base element and a reinforcement structure located on the base element, wherein the reinforcement structure is configured to increase a flexural stiffness of the beam in the reinforcement section for bending in the height direction.

### FIELD

The present disclosure relates to a micromechanical beam for scanning probe measurements, lithography and the like and a method for fabricating such a beam.

### BACKGROUND

Micromechanical beams are, inter alia, employed in atomic force microscopes (AFMs) to measure forces down to the atomic level and to characterize surfaces of various materials. In other applications, micromechanical beams are used as lithographic tools to pattern surfaces. Because of their resolution and versatility, AFMs are important measurement and lithographic devices in many diverse fields ranging from semiconductor manufacturing to biological research.

AFMs based on active beams can obtain resolution down to the atomic level. Recent works in high resolution AFM has been performed on a wide variety of surfaces in air, liquid or vacuum by employing piezoelectric scanners and active beams fabricated as micro-electro-mechanical-systems (MEMS). MEMS-based force sensing (or probe-based instruments) provide high-quality imaging at high imaging rates by using a sharp tip positioned at an end of the beam and by using a low force-load or low tracking force to characterize the surface structure of the sample. In lithographic mode, the tip is modified to engrave information, for example by field-emission electrons, to a sample surface.

In the case of scanning probe microscopes (SPMs), the tip is employed to detect tip-surface interactions and to characterize diverse interactions with the sample down to atomic sizes. The measured interaction forces then relate to the material properties of the surfaces and are used for characterizing interfaces, such as solid-liquid interfaces.

Micromechanical beams may also be employed in parallel for high-throughput probe topology measuring, lithography, electrical measurements, or detections of a wide range of masses, fluids, viscosities or the like.

To allow for high-speed measurements and to minimize wear of the tip positioned at the micromechanical beam, a non-contact mode of operation is typically used. In non-contact mode, the van der Waals forces between the tip and the sample are detected by driving oscillations of the micromechanical beam at its resonance frequency and by positioning the micromechanical beam close to the probe surface. Typical beam oscillation amplitudes are in a range below 1 nm. To control the oscillations of the beam, a lock-in technique is typically applied. For high imaging performance, the bandwidth of the lock-in has to be much higher than the mechanical bandwidth of the beam. The scanning speed in non-contact mode is usually limited by the time the oscillating micromechanical beam requires to adapt to changes of the surface topology upon movement of the probe tip over the surface.

Usually, bending of the beam when the tip is close to or touches a surface is detected by reflecting a laser beam off the micromechanical beam and by measuring the laser beam direction with a split photodetector. The bending of the micromechanical beam then reveals the tip-sample interaction force. This approach for probe measurement is called optical read-out or Optical Beam Deflection (OBD) readout. While optical read-out is the most common method to detect the deflection of beams, it is however limited by diffraction at the micromechanical beam, which prevents downscaling of conventional scanning probes to single micrometers.

Accordingly, there is a need to provide a scanning beam design and a method for fabricating such a beam that allows for scanning a surface with high speed and to thereby obtain high quality, high resolution measurements.

### SUMMARY

The present disclosure provides a micromechanical beam for scanning probe measurements, lithography and the like, the micromechanical beam extending in a longitudinal direction between a fixed end and a free end. The beam has a height along a height direction perpendicular to the longitudinal direction, the height being smaller than a width along a width direction. Furthermore, the beam has a bending section that is located in the longitudinal direction at the fixed end of the beam and a reinforcement section that is located in the longitudinal direction between the bending section and the free end. In the reinforcement section, the beam has a base element and a reinforcement structure located on the base element, wherein the reinforcement structure is configured to increase a flexural stiffness of the beam in the reinforcement section for bending in the height direction.

The present disclosure is based on the insight that the mechanical bandwidth of the beam at its resonance frequency limits the measurement speed and the resolution that is obtainable in scanning operation. A beam with a higher mechanical bandwidth has a faster response to topography differences and is much better suited for high speed measurements than a beam having a lower mechanical bandwidth. A high mechanical bandwidth therefore enables a high sensing and scanning speed.

Besides external effects like the damping of the beam in the surrounding medium and the stiffness of the sample at the location where the beam is scanning, the mechanical bandwidth of the beam is determined by the spring constant and the effective mass of the beam. The bandwidth thereby increases with decreasing effective mass. Therefore, a reduction of the effective mass of the beam allows for an increase in bandwidth and thus also for a higher scan speed. The ratio of the spring constant over the effective mass also is proportional to the resonance frequency of the beam, whereby higher resonance frequencies allow faster scan speeds. The reinforcement structure according to the present disclosure then serves to increase a ratio of stiffness over mass of the beam and at the same time allows to reduce the mass of the beam while keeping the stiffness constant.

Increasing the mechanical bandwidth of the beam while keeping the resonance frequency constant is equivalent to increasing the relative damping of the oscillatory motion of the beam. Damping of the beam may be characterized by a dimensionless parameter Q, which is also called the quality-factor or Q-factor. It describes the rate of the energy transformation in a system and is proportional to the ratio between energy deposited in the system and energy loss over an oscillation period. The quality factor Q is generally defined as the resonance frequency divided by the width of the resonance at half the maximum energy, i.e. Q=fᵣₑₛ/Δf. The beam mechanical bandwidth (defined as fᵣₑₛ/Q) increases when reducing the mass of the beam, for example by reducing the dimensions of the beam and/or by using a lighter material for the beam. The decrease in effective mass that is enabled by the reinforcement structure may amount to a reduction of the Q-factor by at least one order of magnitude so that the mechanical bandwidth of the beam is significantly increased.

Since the reinforcement section and thus also the reinforcement structure are located in between the free end and the fixed end of the beam, bending of the beam predominantly occurs within the bending section at the fixed end of the beam while bending of the remaining freestanding part of the beam is suppressed. This concentration of the bending within the bending section enhances the stress within the bending section so that the bending section is particularly suited for the placement of a read-out structure that is susceptible to the local stress of the beam, such as a piezoresistive read-out structure.

Without the reinforcement structure, stress induced by bending the beam is distributed along the entire length of the beam. The reinforcement section however only allows bending of the beam between the fixed end and the beginning of the reinforcement section, which by itself is practically in-deformable. The stress in the bending region of the beam with the reinforcement structure may be at least 9 times, such as least 12 times, at least 15 times of at least 18 times higher than without the reinforcement structure. For example, the stress may be 18.7 times higher for a beam with reinforcement structure than for the beam without the reinforcement structure.

Compared to a beam having no reinforcement structure, the reinforcement structure allows, on the one hand, to decrease the mass of the beam while keeping its stiffness constant or, on the other hand, to increase the stiffness while keeping the mass constant. Furthermore, the reinforcement structure serves to concentrate the stress of the beam upon bending within the bending section. This enhances the sensitivity of stress-based measurement schemes, such as piezo-resistive readout measurements, performed within the bending region.

In summary, providing the reinforcement structure within the reinforcement section of the beam allows for high scan rates and a sensitive readout of beam oscillations.

The beam may comprise a probe structure that is located at the free end of the beam. The probe structure may be configured to interact with a sample surface located next to the beam. The probe structure may be, for example, configured as a sharp tip, a cylinder or the like. The probe structure may comprise a crystal material. For example, the probe structure may comprise the material of the beam. The probe structure may also comprise or consist of a material that is different from the material of the beam. For example, the probe structure may also comprise a soft and/or a biologic material, such as a molecule or the like. The probe structure may also comprise a hard material like diamond of gallium nitride.

The longitudinal direction, the width direction and the height direction are orthogonal to each other. A length of the beam in the longitudinal direction may be larger than the height of the beam and/or the width of the beam. The beam may be configured as a plate, whereby the height is smaller than the length and the width, for example, by a factor of at least 10, 25, 50 or 100.

The beam is generally configured to oscillate in the height direction. A resonance frequency for the first bending mode of the beam in the height direction may be at least 30 kHz, such as at least 40 kHz, 50 kHz, 55 kHz or 60 KHz. Additionally or alternatively, the resonance frequency of the first bending mode may be at most 10 MHz, such as at most 5 MHz, at most 2 MHz, at most 500 kHz, 400 kHz, 300 kHz, 275 kHz or 250 kHz.

The fixed end of the beam may be clamped to a support structure. The support structure has a larger height along the height direction than the beam. The beam and the support structure may be fabricated from the same material. For example, the beam may be integrally formed with the support structure. Alternatively, the support structure may be separated from the beam by an intermediate layer. For example, the support structure and the beam may be made from silicon and the intermediate layer may be configured as a silicon oxide layer.

The base element may have a rectangular cross section perpendicular to the longitudinal direction within the entire reinforcement section. The base element may have a constant height in the height direction within the entire reinforcement section. Additionally or alternatively, a height of the reinforcement structure may be constant within the entire reinforcement section.

The beam may comprise a base material, such as silicon or diamond. The base element within the reinforcement section may comprise, for example consist of, the base material. The probe structure may also comprise, for example consist of, the base material. Furthermore, also the support structure may comprise, for example consist of, the base material.

The beam may also comprise a base element within the bending section. The base element of the bending section may be made from the base material. A height of the base element of the bending section may equal the height of the base element of the reinforcement section. The base element of the bending section may be formed integrally with the base element of the reinforcement section.

The length of the beam in the longitudinal direction may be at least 20 μm, such as at least 30 μm or at least 40 μm. The length of the beam may be at most 500 μm, such as at most 450 μm, at most 400 μm or at most 350 μm. For example, the length may be between 150 μm and 400 μm. The length may be between 150 μm and 170 μm, such as 165 μm, or between 325 μm and 375 μm, such as 350 μm.

A length of the reinforcement structure along the longitudinal direction may be at least 0.25, such as at least 0.3, at least 0.4, at least 0.45 or at least 0.5 times the length of the beam along the longitudinal direction. The length of the reinforcement structure in the longitudinal direction may be at most 0.75, such as at most 0.7, at most 0.6, at most 0.55 or at most 0.5 times the length of the beam along the longitudinal direction. Reinforcement structures having such a length provide, on the one hand, a sufficient increase of the stiffness of the beam and, on the other hand, allow to integrate additional structures along the longitudinal extent of the beam.

The length of the reinforcement structure may be between 10 μm and 300 μm, such as between 15 μm and 200 μm or between 15 μm and 60 μm. For example, the length of the reinforcement structure may be between 50 μm and 250 μm. The length of the reinforcement structure may be between 40 μm and 360 μm, such as between 75 μm and 270 μm or between 80 μm and 200 μm. The length of the reinforcement structure may be between 40 μm and 160 μm, such as between 75 μm and 100 μm or between 80 μm and 95 μm. The length of the reinforcement structure may also be between 90 μm and 360 μm, such as between 135 μm and 270 μm or between 160 μm and 200 μm.

A width of the reinforcement structure along the width direction may be at least 0.2, such as at least 0.3, at least 0.4, at least 0.5, at least 0.55, at least 0.6, at least 0.7, at least 0.75, at least 0.8 or at least 0.85 times a minimum width of the base element in the reinforcement section. The width of the reinforcement structure may be at least 0.2, such as at least 0.3, at least 0.4, at least 0.5, at least 0.55, at least 0.6, at least 0.7, at least 0.75, at least 0.8 or at least 0.85 times a maximum width of the base element in the reinforcement section. For example, the width of the reinforcement structure may be between 0.8 and 0.95 times or between 0.85 and 0.9 times, such as 0.88 times, the minimum width of the base element in the reinforcement section and/or between 0.5 and 0.7 times or between 0.55 and 0.65 times, such as 0.6 times, the maximum width of the base element in the reinforcement section.

The width of the reinforcement structure may be between 10 μm and 240 μm, such as between 15 μm and 150 μm or between 15 μm and 40 μm. The width of the reinforcement structure may be between 35 μm and 240 μm, such as between 50 μm and 180 μm or between 65 μm and 130 μm. The width of the reinforcement structure may be between 60 μm and 240 μm, such as between 90 μm and 180 μm or between 110 μm and 130 μm. The width of the reinforcement structure may also be between 35 μm and 140 μm, such as between 50 μm and 105 μm or between 65 μm and 75 μm.

A length of the bending section along the longitudinal direction may be at least 0.05, such as at least 0.06, at least 0.07, at least 0.08, at least 0.09 or at least 0.1 times the length of the beam along the longitudinal direction. The length of the bending section may be at most 0.4, such as at most 0.3, at most 0.2, at most 0.15 or at most 0.11 times the length of the beam along the longitudinal direction. Bending sections having such a length provide, on the one hand, a sufficient flexibility and, on the other hand, a concentration of the stress induced by bending in a region adapted for efficient readout.

The length of the bending section may be between 2.5 μm and 80 μm, such as between 2.5 μm and 30 μm. For example, the length of the bending section may be between 5 μm and 15 μm. The length of the bending section may be between 10 μm and 80 μm, such as between 15 μm and 60 μm or between 18 μm and 45 μm. The length of the bending section may be between 20 μm and 80 μm, such as between 30 μm and 60 μm or between 35 μm and 45 μm. The length of the bending section may also be between 10 μm and 40 μm, such as between 15 μm and 30 μm or between 18 μm and 25 μm.

According to an embodiment, the reinforcement structure is located at a surface of the base element that is essentially perpendicular to the height direction. Compared to other surfaces, this provides for an efficient reinforcement of the beam in the reinforcement section.

According to an embodiment, the reinforcement structure and the probe structure are located at the same surface of the base element. This allows for fabrication of both the reinforcement structure and the probe structure from the same side of the base element and thus facilitates production of the micromechanical beam.

According to an embodiment, the reinforcement structure projects from the base element as a free-standing structure. Such free-standing structures provide efficient reinforcement.

According to an embodiment, the beam comprises a layer of passivation that is located on a surface of the beam. The reinforcement structure thereby comprises, for example consists of, the same material as the layer of passivation. For example, the reinforcement structure may be formed by structuring the layer of passivation. The material of the layer of passivation may, for example, be a silicon nitride or Si3N4 and/or a silicon oxide or SiO2.

According to an embodiment, in the reinforcement section and for bending in the height direction, the flexural stiffness of the base element with the reinforcement structure is larger, for example by at least a factor of 1.2, 2.5, 5, 8, 10, 15 or 20, than the flexural stiffness of the base element without the reinforcement structure. Such an increase in stiffness allows for a significant reduction in mass of the beam and thus also for a significant increase in bandwidth. The flexural stiffness of the base element without the reinforcement structure may be the flexural stiffness of the base element within the reinforcement section.

According to an embodiment, the flexural stiffness of the beam for bending in the height direction is by a factor of at least 1.1, such as by a factor of at least 1.2, at least 1.4, at least 1.5, at least 2, at least 2.5 or at least 4, higher in the reinforcement section than in the bending section. Such a ratio of the stiffness in the reinforcement section and the bending section effectively concentrates the stress caused by an oscillation of the beam within the bending section, which has a lower stiffness than the reinforcement section.

According to an embodiment, a cross section of the base element and the reinforcement structure in a plane perpendicular to the longitudinal direction has a second axial moment of area for bending around an axis parallel to the width direction that is larger, such as by a factor of at least 5, at least 10, at least 12 or at least 13 larger, than a second axial moment of area of a rectangle that has the same width as the base element and that has the same area as the cross section of the base element and the reinforcement structure in the plane perpendicular to the longitudinal direction. Compared to a beam having a rectangular cross section, the increase in the second axial moment of area of the beam according to the present disclosure allows for a significant reduction in size and mass of the beam without reducing the stiffness compared to a rectangular beam. The smaller and lighter beam then allows for an increase in bandwidth compared to a rectangular beam. The second axial moment of area may also be denoted as moment of inertia or area moment of inertia.

Alternatively or additionally, for bending around an axis parallel to the width direction, said second axial moment of area of the cross section of the base element and the reinforcement structure in a plane perpendicular to the longitudinal direction may be larger, such as by a factor of at least 1.05, at least 1.1, at least 1.15 or at least 1.2 larger, than a second axial moment of area of a cross section of only the base element within the reinforcement section and in the plane perpendicular to the longitudinal direction.

According to an embodiment, for bending around an axis parallel to the width direction, the second axial moment of area of a cross section of the beam perpendicular to the longitudinal direction is larger, such as by at least a factor of 1.1, such 1.15, 1.2, 1.25, 1.3 or 1.4 larger, in the reinforcement section than in the bending section. This efficiently concentrates the stress occurring upon oscillation of the beam around the axis parallel to the width direction within the bending section and facilitates a stress-based readout of the oscillation within the bending section.

According to an embodiment, the cross section of the base element and the reinforcement structure in a plane perpendicular to the longitudinal direction may have an area that is smaller, for example smaller by a factor of at least 1.05, 1.08 or 1.1, than an area of a rectangle that has the same width as the base element and that has the same second axial moment of area as said cross section of the base element and the reinforcement structure. The reduction in area results in a lower mass and thus also in a larger bandwidth of the beam according to the present disclosure compared to a rectangular beam and thus enables higher scan speeds.

According to an embodiment, a height of the reinforcement structure in the height direction amounts to at least 0.1, such as at least 0.2, at least 0.25, at least 0.5 or at least 1 time a height of the base element in the height direction. A larger height of the reinforcement structure also increases the stiffness of the beam within the reinforcement section that allows a reduction in mass without simultaneously reducing the stiffness of the beam. The height of the reinforcement structure may be at least 0.05 μm, at least 0.1 μm, at least 0.25 μm, at least 0.5 μm, at least 1 μm, at least 2 μm, at least 5 μm or at least 10 μm.

The height of the reinforcement structure may be at most 1 time, 1.5 times, 2 times, 2.5 times or 5 times the height of the base element.

For example, the height of the reinforcement structure may be at most 2.5 μm, at most 3 μm, at most 3.5 μm, at most 4 μm, at most 5 μm, at most 6 μm, at most 10 μm, at most 15 μm, at most 20 μm or at most 40 μm.

The height of the reinforcement structure may be between 0.7 μm and 5 μm. The height may be at least 0.7 μm, at least 1 μm, at least 1.5 μm, at least 2 μm, at least 2.5 μm, at least 3 μm, at least 3.5 μm, at least 4 μm, or at least 4.5 μm. The height may be at most 1 μm, at most 1.5 μm, at most 2 μm, at most 2.5 μm, at most 3 μm, at most 3.5 μm, at most 4 μm, at most 4.5 μm, or at most 5 μm.

A Young's modulus of at least one material layer of the reinforcement structure or of the reinforcement structure may be at least 100 GPa, such as at least 150 GPa, at least 200 GPa, at least 250 GPa, at least 300 GPa, at least 350 GPa, or at least 400 GPa. For example, the Young's modulus may be 411 GPa, for example with the material layer made from tungsten, or 330 GPa, for example with the material layer made from molybdenum. For example, the material layer may have a height that is at least 10%, at least 20%, at least 30%, at least 40%, at least 50%, at least 60%, at least 70%, at least 80%, or at least 90% the height of the reinforcement structure.

The Young's modulus of the at least one material layer of the reinforcement structure or of the reinforcement structure may be at least 3.5 times, such as at least 4 times, at least 4.5 times, at least 5 times, at least 5.5 times, at least 6 times, at least 6.5 times, or at least 7 times the Young's modulus of the base material of the base element. This provides for efficient stiffening of the micromechanical beam within the reinforcement section.

According to an embodiment, the reinforcement structure comprises at least one ridge that extends parallel to the longitudinal direction. Longitudinal ridges provide an effective measure to enhance the stiffness of the beam for bending perpendicular to the ridge. The ridge increases viscosity of the surface of the beam, which results in higher damping and lower Q-factor.

According to an embodiment, an aspect ratio of the height of the ridge in the height direction over the width of the ridge in the width direction is at least 0.1, such as at least 0.2 or at least 0.25. Since the stiffness of the reinforcement structure increases with increasing aspect ratio of the ridge, ridges with a high aspect ratio provide an efficient reinforcement of the beam. The height of the ridge may equal the height of the reinforcement structure.

For example, the aspect ratio may be at least 0.5, at least 1, at least 2.5, at least 3, or at least 3.5. For example, the aspect ratio may be larger than 2.5.

A ratio of a width of the ridge to the height of the base element may be at least 0.4, at least 0.8, at least 1.5, at least 2.5, at least 3 or at least 4. Additionally or alternatively, the ratio of the width of the ridge to the height of the base element may be at most 4, at most 5, at most 8, at most 20 or at most 40. For example, the ratio of the width of the ridge to the height of the base element may be 4.

The ridge may have a width of at least 0.05 μm, at least 0.1 μm, at least 0.25 μm, at least 0.4 μm, at least 0.5 μm, at least 1 μm, at least 2 μm, at least 3 μm, at least 4 μm or at least 4.5 μm. Additionally or alternatively, the ridge may have a width of at most 3 μm, at most 4 μm, at most 4.5 μm at most 5 μm, at most 6 μm or at most 10 μm. For example, the width of the ridge may be 4.5 μm.

The width of the ridge may be between 0.7 μm and 2 μm. The width may be at least 0.7 μm, at least 0.8 μm, at least 1 μm, at least 1.25 μm, at least 1.5 μm, or at least 1.75 μm. The width may be at most 0.8 μm, at most 1 μm, at most 1.25 μm, at most 1.5 μm, at most 1.75 μm, or at most 2 μm.

According to an embodiment, the reinforcement structure comprises several ridges, such as at least two ridges, extending in parallel to the longitudinal direction and being placed next to each other along the width direction. This further increases the stiffness of the beam in the reinforcement section.

The individual ridges may have the same height and/or the same width. A spacing between the individual ridges, that is a width of gaps in between the individual ridges, may be at least 0.1 times, at least 0.25 times, at least 0.5 times, at least 0.75 times or at least 1 time the width of the ridges. Additionally or alternatively, the spacing may be at most 0.5 times, at most 0.75 times, at most 1 time, at most 1.5 times or at most 2 times the width of the ridges.

The spacing or width of the gaps in between the ridges may be at least 0.05 μm, at least 0.1 μm, at least 0.25 μm, at least 0.4 μm or at least 0.5 μm. Additionally or alternatively, the gaps may have a width of at most 3 μm, at most 4 μm, at most 6 μm or at most 10 μm.

The gaps may have a width of at least 0.75 μm, at least 1 μm, at least 1.25 μm, at least 1.5 μm, at least 1.75 μm, at least 2 μm, at least 2.25 μm, at least 2.5 μm, at least 2.75 μm, or at least 3 μm. The gaps may have a width of at most 1 μm, at most 1.25 μm, at most 1.5 μm, at most 1.75 μm, at most 2 μm, at most 2.25 μm, at most 2.5 μm, at most 2.75 μm, at most 3 μm, at most 3.25 μm, at most 3.5 μm, at most 3.75 μm, at most 4 μm, at most 4.25 μm, or at most 4.5 μm.

According to an embodiment, the ridges have a same width in the width direction and/or a same height in the height direction. This allows for simple and reliable fabrication of the ridges.

The reinforcement structure may comprise one ridge or several ridges. For example, the reinforcement structure may comprise at least 2, at least 4, at least 6, at least 10, at least 15, at least 20, at least 30, at least 50, at least 75, or at least 90 ridges. The reinforcement structure may comprise at most 2, at most 4, at most 6, at most 10, at most 15, at most 20, at most 30, at most 50, at most 75, at most 90 ridges, or at most 100 ridges.

According to an embodiment, neighboring ridges of the reinforcement structure are connected to each other at alternating longitudinal ends to form a meandering structure. This allows to integrate the ridges into other functional structures of the micromechanical beam. For example, the ridges may form part of an electrically conducting structure or a support for such an electrically conducting structure of the beam. Connecting the ends of the ridges then provides a continuous path for current flow through the conducting structure.

The reinforcement structure may comprise an even number of connected ridges so that both ends of the meandering structure are located at the same end of the beam, for example at the fixed end of the beam. This allows to couple a conducting structure associated with the reinforcement structure to a source of electric energy at the respective end of the beam.

According to an embodiment, the reinforcement structure is a continuous structure in a plane perpendicular to the height direction that continuously runs from a first end to a second end. Such a reinforcement structure may, for example, be configured as a meandering structure. It may comprise a meandering ridge that continuously runs from the first end to the second end.

For example, the first end and/or the second end may be located at an end of the reinforcement section that faces towards the fixed end of the micromechanical beam. For example, the first end and the second end may be located at the same end of the reinforcement section, such as at the end of the reinforcement section that faces towards the fixed end of the micromechanical beam. This allows, for example, to form an electrically conducting structure as part of the reinforcement structure or on top of the reinforcement structure.

According to an embodiment, the reinforcement structure forms part of an electrically conducting structure or forms a support for the electrically conducting structure. The electrically conducting structure thereby may provide a continuous path for current flow.

According to an embodiment, the micromechanical beam comprises a patterned multi-layer structure, wherein the patterned multi-layer structure comprises the reinforcement structure. For example, the patterned multilayer structure may be homogeneously patterned in the height direction, at least in the reinforcement section, for example over the entire surface of the micromechanical beam and/or over the entire micromechanical beam. The multi-layer structure may be placed on top of the base element, such as on top of the surface of the base element. The multi-layer structure may have been patterned by etching, electroplating, laser cutting, electron-beam machining (EBM) or the like.

Such a multi-layer structure allows for integration of different functional structures into the reinforcement structure. For example, the multi-layer structure may also provide the electrically conducting structure and/or a drive structure.

The reinforcement structure may be made from a semiconductor, a conductor, such as a metal, or an insulator, such as a polymer like acrylic or parylene. The reinforcement structure may be configured as a film, such as an acrylic or parylene film. For example, the reinforcement structure may be made from silicon, silicon oxide, silicon nitride, metal or diamond.

The reinforcement structure may comprise at least one of, several of or all of a semiconductor, a conductor, such as a metal, and an insulator, such as a polymer like acrylic, polyimide or parylene. The reinforcement structure may comprise a film, such as an acrylic or parylene film. For example, the reinforcement structure may comprise at least one of, several of or all of silicon, silicon oxide, silicon nitride, metal and diamond.

According to an embodiment, the reinforcement structure and the base element are at least partly materially uniform and integrally joined together. This provides a reliable connection between the base element and the reinforcement structure and further stiffens the beam within the reinforcement section. For example, the reinforcement structure at least partly may have been formed by selectively removing parts of the material from which the base element is formed. The parts may, for example, have been removed by etching, laser cutting, electron-beam machining (EBM) or the like.

According to an embodiment, the reinforcement structure comprises a material that is different from a base material of the base element. For example, the reinforcement structure may be entirely made from materials that are different from the base material of the base element. The material that is different from the base material may be, for example, a metal.

According to an embodiment, the beam comprises an electrically conducting metal structure on top of the reinforcement structure that is galvanically isolated from the reinforcement structure. Such a metal structure may, for example, serve to heat the beam. Additionally or alternatively, the metal structure may also be configured as a thermomechanical actuator, such as a bimetallic actuator. The metal structure may be made from a different material than the reinforcement structure.

With other embodiments, the reinforcement structure may also comprise the electrically conducting metal structure. For example, the reinforcement structure may consist of the electrically conducting metal structure.

The metal structure may be galvanically isolated from the reinforcement structure and/or the base element by an insulating protective layer, such as an oxide layer.

The electrically conducting metal structure may be configured at least as part of a current loop. It may form a continuous electrically conducting structure running from a first end to a second end. With embodiments, that comprise a reinforcement structure that only has a single ridge, the first end may be located at one end of the reinforcement section in the longitudinal direction and the second end may be located at the opposite end of the reinforcement section. At one of the ends, for example at the end further away from the fixed end of the micromechanical beam, the metal structure may be electrically conductively connected to the base element of the micromechanical beam and the current loop may be closed via the base element. Along the remainder of the ridge, the metal structure may be electrically insulated from the base element.

With other embodiments, the reinforcement structure may comprise an even number of ridges that are placed next to each other in the width direction and that are connected to each other at alternating longitudinal ends. The electrically conducting metal structure then may form a closed current loop along the ridges, whereby both ends of the conducting metal structure are located at the same side of the reinforcement section in the longitudinal direction, for example at the side facing towards the fixed end of the micromechanical beam.

The closed current loop may form a part of a drive structure to drive mechanical oscillations of the beam.

The beam may comprise a reinforcing element within the bending section. The reinforcing element may be configured to prevent the buildup of stress at the reinforcing element and to thereby concentrate stress induced by bending of the beam in a readout region of the bending region. The reinforcing element may be located at an edge of the beam in the width direction. The reinforcing element may be elongated along the longitudinal direction. For example, the reinforcing element may be configured as an elongated ridge. As far as no differences are disclosed, the reinforcing element may be configured as it is disclosed for the reinforcement structure and vice versa.

The reinforcing element may have a width that is larger than a width of the ridge of the reinforcement structure in the width direction. This increases the stiffening function of the reinforcing element compared to that of the ridge of the reinforcement structure.

The reinforcing element may be separated from the readout region by an opening within the beam. The opening may run parallel to the reinforcing element. Such an opening further concentrates the strain induced by bending of the beam within the readout region.

A width of the opening within the readout structure in the width direction may be at least 0.1, 0.25, 0.5 or 1 times the height of the base element in the bending section. Additionally or alternatively, the width of the opening may be at most 0.5, 1, 2, or 5 times the height of the base element in the bending section.

A width of the opening within the readout structure in the width direction may be at least 0.25 μm, at least 0.3 μm, at least 0.4 μm or at least 0.5 μm. Additionally or alternatively, the width may be at most 5 μm, at most 10 μm, at most 20 μm or at most 50 μm.

With other embodiments, the micromechanical beam may also only comprise the opening but not the reinforcing element. The opening may, for example, run parallel to a longitudinal direction of the micromechanical beam. In addition to the opening, the micromechanical beam may also comprise an additional opening that is located at an opposite side of the beam as the opening.

In addition to the reinforcing element, the beam may also comprise an additional reinforcing element located within the bending section. As far as no differences are disclosed, the additional reinforcing element may be configured as it is disclosed for the reinforcing element and vice versa. The two reinforcing elements may be located at opposite edges of the beam within the bending section. Additionally or alternatively, the readout region may be located in between the two reinforcing elements. This efficiently concentrates the strain induced by bending of the beam within the readout region.

A micromechanical beam having the reinforcing element or the reinforcing elements may also be configured without the reinforcement structure and/or the reinforcement section. The present disclosure therefore also relates to a mechanical beam having only the at least one reinforcing element. All embodiments disclosed for the micromechanical beam having the reinforcement section also apply to the micromechanical beam only having the reinforcing element.

According to an embodiment of the beam comprising the conducting metal structure, the metal structure has two leads that longitudinally extend through the bending section for connection of an electrical power source. The leads may be located on the reinforcing elements within the bending section. For example, the reinforcing element and the additional reinforcing element may carry the leads. With other embodiments, the leads may also form the reinforcing elements.

According to an embodiment, the leads are placed in an edge region of the bending section. This concentrates the strain induced by bending of the beam in between the leads. The edge region may comprise two subregions located at opposite edges of the beam running parallel or essentially parallel to the longitudinal direction. Each subregion may comprise one of the leads. The two subregions may be located at opposite sides of the readout region in the width direction.

According to an embodiment, a width of the leads in the bending section is larger than a width of the ridge of the reinforcement structure. On the one hand, this decreases the resistance of the leads within the bending section and thus also the thermal influence of the leads on the beam within the bending section. Furthermore, wider leads also increase the stiffness of the beam in the region occupied by the leads.

The lateral width of the leads may be at least at least 1.2, at least 1.5, at least 2.0 or at least 2.5 times the height of the base element in the bending region. Additionally or alternatively, the lateral width of the leads may be at most at least 1.2, at least 1.5, at least 2.0 or at least 2.5 times the height of the base element in the bending region.

For example, the lateral width of the leads may amount to at least 0.25 μm, at least 0.3 μm, at least 0.4 μm or at least 0.5 μm. Additionally or alternatively, the lateral width may amount to at most 2.5 μm, at most 5 μm, at most 10 μm or at most 15 μm.

According to an embodiment, the metal structure has at least two conducting layers placed on top of each other in the height direction that form a thermally active multi-metal structure that causes bending strain on the beam upon heating. The metal structure thus may form an actuator for bending the beam in the height direction. For example, the metal structure may be configured to drive oscillations of the beam in the height direction. The individual conducting layers may be made from materials that have differing thermal expansion coefficients. The metal structure may form a thermomechanical actuator.

With other embodiments, the metal structure may also comprise only a single metal layer.

The metal layers, such as the single metal layer, the first metal layer and the second metal layer, of the metal structure may comprise or consist of one of aluminum, tungsten, a tungsten alloy, an aluminum-magnesium alloy, molybdenum, and a molybdenum alloy.

Tungsten and molybdenum are metallic materials that display excellent durability to thermal and mechanical stress, high resistance to corrosion and wear, high melting points, retention of mechanical strength at high temperatures, and high hardness at room temperature. The metal layer may have been formed by dual-target or multi-target magnetron sputtering deposition.

The metal layer, such as the single metal layer, the first metal layer or the second metal layer, may be formed as a polycrystalline layer and/or as a thin film layer, for example as a polycrystalline tungsten or molybdenum layer and/or as a thin film tungsten or molybdenum layer.

The metal layer, such as a tungsten or molybdenum polycrystalline and/or thin film layer, may have been structured by dry etching, for example by reactive ion etching, for example in SF6, and SF6, +N+CHF3 gas mixtures. Electron energies during etching may be at most 100 eV, 75 eV or 50 eV or less than 100 eV, 75 eV, or 50 eV. Such energies provide for small undercuts at the edges of the metal layer.

A thermal expansion coefficient of at least one metal layer, such as of each metal layer, may differ from a thermal expansion coefficient of the base material of the base layer by at most 5%, 10%, 20%, 30%, 40%, 50%, 60%, 70%, 80%, 90% or 100%. This matches thermal expansion coefficients of the metal layer and the base material to prevent damage to the cantilever resulting from thermal stress. Furthermore, the thermal expansion coefficient of at least one metal layer, such as of each metal layer, may differ from the thermal expansion coefficient of the base material of the base layer by at least 2.5%, 5%, 10%, 20%, 30%, 40%, 50%, 60%, 70%, 80%, 90% or 95%. This provides for efficient driving of a bending of the micromechanical beam upon heating of the metal layer, such as upon resistive heating of the metal layer.

According to an embodiment, the reinforcement structure has been formed by etching the base element using the metal structure as an etch mask. This allows for cost-effective manufacturing of the beam since it eliminates the need for defining a separate etch mask for manufacturing the reinforcement structure.

According to an embodiment, the beam has a further reinforcement structure that is located in the reinforcement section and that is placed at a further surface of the base element of the beam, wherein the surface and the further surface are parallel to each other and located at opposing sides of the base element in the height direction. The further reinforcement structure enhances the stiffness of the beam in addition to the reinforcement structure.

The further reinforcement structure may comprise one or more longitudinal ridges that are elongated parallel to the longitudinal direction. The one or more ridges may be located at a longitudinal edge of the beam. For example, the further reinforcement structure may comprise two longitudinal ridges that are located at opposing longitudinal edges of the beam.

According to an embodiment, the beam has a readout structure, for example a piezo-resistive readout structure and/or Wheatstone bridge, for measuring mechanical oscillations of the beam in the height direction, wherein the readout structure is located in the bending section of the beam. Due to the reinforcement structure, stress induced by bending of the beam in the height direction is concentrated in the bending region. Therefore, placing the readout structure within the bending section enhances the sensitivity of the readout to the bending of the beam.

The readout structure may be configured as a strain-sensitive readout structure, such as a piezo-resistive readout structure and/or a Wheatstone bridge. Compared to optical readout, a strain-sensitive readout structure may be integrated in a smaller area than needed for reflecting a laser beam from the surface of the micromechanical beam. For example, optical readout requires a minimum reflective area on the beam backside. This area is in the range of 3 μm×9 μm in high-end systems, which requires a small laser spot. Compared to readout structures directly placed on the surface of the beam, optical read-out methods additionally require bulky optical components, their mechanical adjustment, and access to very precise mechanical alignment. The optical components usually are bulky and take up a lot of space, therefore increasing the instruments physical dimensions. This poses difficulties for fast scanning with very small beams (1 μm×3 μm) and operation in closed vacuum or cryogenic chamber environments. Direct integration of the readout structure on the beam hence allows further beam miniaturization.

In general, a readout structure configured as a stress-sensitive structure provides an alternative to OBD readout and the ability to image in diverse environments, such as vacuum, air, or liquids. A stress-sensitive readout structure measures beam deflection through the stress induced in the beam within the sensor area. The stress is proportional to the thickness of the beam. Thicker beams mean higher stiffness of the beam (e.g. larger than 100 N/m). Such beams are usually not appropriate for imaging soft samples, such as polymers or bio-materials. Thick beams usually require large forces between the probe structure and the sample, which usually cause a high wear or breaking of the probe structure.

The sensitivity of the stress-sensitive readout structure on beam deflection, that is the minimum measurable deflection, depends on the stress generated in the readout structure, for example in a Wheatstone bridge circuit. Therefore, the readout structure is positioned at the regions of maximum stress—the top or bottom surface of the beam within the bending section, which is located at the fixed end of the beam. Furthermore, stress-sensitive readout structures are suited for beams in which a high stress is induced when the beam is deflected or bended. By reinforcing the beam with the reinforcement structure in between the free end and the readout structure, a high stress is obtained without increasing the spring constant of the beam in the bending region. This leads to a beam that is still sensitive to small forces and/or loads. For example, the beam may be configured to detect forces between 10⁻¹⁵ N and 10⁻¹⁸ N acting between the probe structure and the sample.

The readout structure may comprise a Wheatstone bridge that has resistors fabricated from piezo-resistive materials. The Wheatstone bridge may be configured as a full Wheatstone bridge. The resistors may be fabricated as thin film resistors. The readout structure may encircle an opening within the beam. Such an opening further concentrates the stress in the region of the resistors of the readout structure.

In addition or alternatively to the opening encircled by the Wheatstone bridge, the beam may comprise one or more additional openings located next to the readout structure. For example, the one or more additional openings may be configured as longitudinal openings or slots. They may be elongated parallel to the longitudinal direction. Each additional opening may be located in between a longitudinal edge of the beam and the readout structure. For example, the beam may have to additional openings that are located on either side of the readout structure in the width direction and which are placed in between a longitudinal axis of the beam and the readout structure.

The opening encircled by the readout structure and/or the additional openings may be configured to reduce the stiffness within the readout region by at most 5%, by at most 2.5%, by at most 1%, such as by 1% compared to the same beam without openings. Furthermore, the openings may be configured to increase the sensitivity of the readout structure by at least 5%, such as by at least 7.5% or by at least 10%, such as by 10% compared to the same beam without openings.

The readout structure may have a bandwidth of at least 10 kHz, at least 15 kHz or at least 20 kHz, such as 50 KHz. A vertical resolution of the readout structure may be between 0.1 nm and 25 nm, for example between 0.1 nm and 15 nm, such as 12 nm. The readout structure may be configured to detect thermally induced oscillations of the beam in air and/or liquid and/or vacuum and at room temperature at resonance without external actuation.

According to an embodiment, the readout structure is located in between two leads of the metal structure. This further concentrates the stress induced by bending the beam within the area of the readout structure.

According to an embodiment, the beam has at least one lateral cutout that is located in the bending section. Such a lateral cutout further concentrates the stress induced by bending of the beam in regions towards the center of the beam. The lateral cutout may be located at a longitudinal edge of the beam.

A length of the cutout parallel to the longitudinal direction and a width of the cutout parallel to the width direction may have a ratio of the width over the length of at least 0.5, at least 0.75, at least 0.8, at least 0.9 or at least 0.95. Furthermore, the ratio of width, length may be at most 2, at most 1.5, at most 1.25, at most 1.1 or at most 1.05.

The cutout may be tapered along the width direction. For example, a length of the cutout parallel to the longitudinal direction may be larger at the edge of the beam than towards the center of the beam. The ratio of the width over the length of the cutout may apply to the length of the cutout at the edge of the beam.

According to an embodiment, the beam has two lateral cutouts that are located in the bending section at opposite side surfaces of the beam in the width direction.

The single lateral cutout or the two lateral cutouts may narrow the width of the beam to at most 0.85, such as at most 0.8, at most 0.75, at most 0.7 or at most 0.5 times a maximum lateral width of the beam in the bending section.

According to an embodiment, the width of the beam at the cutouts deviates from a minimum lateral width of the beam at the cutouts by less than 20% such as less than 10% or less than 5% or less than 1% over a longitudinal length that is at least equal to a longitudinal length of the readout structure. Such cutouts narrow the beam over the entire longitudinal length of the readout structure and therefore efficiently concentrate the stress induced by bending of the beam at the readout structure.

The present disclosure also generally relates to a micromechanical beam that has the at least lateral cutout in the readout section but does not feature the reinforcement structure. All further embodiments that are disclosed in connection with the micromechanical beam according to the present disclosure that features the reinforcement structure also apply to the micromechanical beam that only has the at least one lateral cutout but not the reinforcement structure.

According to an embodiment, the beam comprises a drive structure that is configured to excite mechanical oscillations of the beam in the height direction, wherein the drive structure is located within the reinforcement section. A beam having a drive structure is adapted to active sensing whereby an interaction between the probe structure of the beam and the sample is sensed by a shift of the resonance frequency of the beam during a driven oscillation. A direct integration of the drive structure onto the beam allows for beam miniaturization. Moreover, an integration of the drive structure allows a very compact measurement setup that occupies little space and allows for use in large beam arrays. By placing the drive structure in the reinforcement section in between the free end and the fixed end of the beam, oscillations may be efficiently driven by the drive structure.

The drive structure may be configured as a thermomechanical actuator. It may comprise a multilayer structure of at least two layers of materials featuring differing thermal expansion coefficients. The differing thermal expansion coefficients of the layers result in bending of the beam by means of differing extensions of the layers. This allows to precisely control the displacement of the beam by the electrical power dissipated in the embedded resistors formed by the stacked layers. The drive structure may comprise at least two thin film layers.

The drive structure may be formed by the electrically conducting metal structure, such as the electrically conducting metal structure on top of the reinforcement structure. Alternatively, the drive structure may also be formed by the reinforcement structure itself. The reinforcement structure may also comprise the drive structure.

The drive structure may be configured to be controlled to change its temperature, for example to heat, either by internal temperature control, such as conductive and/or resistive energy transfer, or by external temperature control, such as radiative energy transfer. Thermomechanical actuation may also be called bimorph actuation.

In general, the beam may be configured to oscillate at or near a resonant frequency, whereby the oscillation is driven by the drive structure in order to provide relative oscillatory motion of the probe structure of the beam across a sample surface. When the beam is in alternating distance to a sample surface, an oscillation amplitude and/or an oscillation phase of the beam is modulated by beam-sample interactions. The beam may be configured to be controlled to keep the oscillation amplitude and/or the oscillation phase constant during scanning using feedback signals, which are generated in response to tip-sample interaction, for example by the readout structure. These feedback signals then may be used to determine properties of the sample surface.

According to an embodiment, the reinforcement structure is formed by a material different from a material of the drive structure.

According to an embodiment, the beam comprises at least one longitudinal slot that extends over the length of the bending section. The longitudinal slot may form the opening or the additional opening that run parallel to the reinforcing element in the readout section and/or that are located next to the readout structure, such as between the readout structure and an edge of the beam.

According to an embodiment, in the reinforcement section, the beam tapers down along the longitudinal direction by a factor of at least 0.1, such as at least 0.2 or at least 0.25 in the width direction. For example, the beam may taper down towards its free end. This further concentrates the mass of the beam towards its fixed end and increases the bandwidth of the beam.

The present disclosure also generally relates to a mechanical beam that has the taper along the longitudinal direction but does not feature the reinforcement structure. All further embodiments that are disclosed in connection with the micromechanical beam according to the present disclosure that features the reinforcement structure also apply to the micromechanical beam that only has the taper but not the reinforcement structure.

The present disclosure is also directed at a sensing system comprising the micromechanical beam according to the present disclosure and a control system coupled to the micromechanical beam. The control system may comprise an actuation module and/or a readout module.

The actuation module may be coupled to the drive structure and may be configured to drive a bending of the beam by the drive structure. For example, the drive structure may be configured to generate an alternating current and/or a pulsed current that is fed to the drive structure, for example via the leads of the metal structure that forms the drive structure. The leads thereby may extend through the bending section of the beam.

The readout module may be coupled to the readout structure and may be configured to determine a bending of the beam by the readout structure. For example, the readout module may be configured to sense the stress within the bending section with the readout structure. To this end, the readout module may be configured to sense changes of the resistance within the Wheatstone bridge and to determine the bending of the beam from the resistance.

The control system may also comprise a scanning module that is configured to effect relative movement between the beam and a sample. The scanning module may, for example, comprise mechanical actuators. The scanning module may be configured to move the beam relative to the sample and/or to move the sample relative to the beam in the width direction and/or the longitudinal direction and/or the height direction.

The control system may also comprise a control module that is configured to control the actuation of the beam by the actuation module and/or to receive information on the bending of the beam from the readout module. The control module may be configured to drive oscillations of the beam via the actuation module. A frequency of the oscillations may be swept across the mechanical resonance of the bending motion of the beam. The control module may be further configured to determine an amplitude and/or a phase of the oscillation of the beam from the information received via the readout module and to generate feedback signals that control the motion of the beam to keep the amplitude and/or the phase of the oscillation constant. Furthermore, the control module may be configured to move the beam with respect to the sample via the scanning module and to output the feedback signals generated upon that movement.

The present disclosure is also directed at a method for fabricating a micromechanical beam, the method comprising:
providing a base material of the beam;
fabricating a reinforcement structure at a surface of the base material that is perpendicular to a height direction;
fabricating a free standing beam from the base material,
wherein the beam extends along a longitudinal direction between a fixed end and a free end,
wherein the beam has a height along a height direction perpendicular to the longitudinal direction, the height being smaller than a width along a width direction,
wherein the beam has a bending section that is located in the longitudinal direction at the fixed end of the beam and a reinforcement section that is located in the longitudinal direction between the bending section and the free end,
wherein the reinforcement structure is located within the reinforcement section, and
wherein the reinforcement structure is configured to increase a flexural stiffness of the beam in the reinforcement section for bending in the height direction.

The micromechanical beam may be the micromechanical beam according to the present disclosure. All embodiments and technical effects disclosed for the micromechanical beam also apply to the method and vice versa.

According to an embodiment, fabricating the reinforcement structure comprises:
providing a metal structure having leads for connection with an electrical power source on the surface of the base material;
etching the base material parallel to the height direction using the metal structure as an etch mask.

The present disclosure is also directed at a method for sensing a sample with the micromechanical beam according to the present disclosure. The method comprises placing the beam, such as the probe structure of the beam, next to the sample, driving an oscillation of the beam and sensing changes of the oscillation due to interactions between the sample and the beam. The method may be performed by the control system according to the present disclosure. All embodiments and technical effects disclosed for the control system also apply to the method for sensing and vice versa.

The sensing of the changes of the oscillation may comprise sensing for determining a shift of a resonance frequency of the oscillation induced by the interactions between the sample and the beam.

The method may comprise driving a bending of the beam by the drive structure. For example, the method may comprise generating an alternating current and/or a pulsed current and feeding the current to the drive structure, for example via the leads of the metal structure that forms the drive structure.

The method may comprise determining a bending of the beam. For example, the method may comprise sensing the stress induced upon the bending. The method may comprise sensing changes of the resistance within the Wheatstone bridge and determining the bending of the beam from the changes in resistance.

The method may comprise effecting relative movement between the beam and the sample. The method may comprise moving the beam relative to the sample and/or moving the sample relative to the beam.

The method may comprise controlling the actuation of the beam and/or receiving information on the bending of the beam. The method may comprise driving oscillations of the beam. A frequency of the oscillations may be swept across the mechanical resonance of the bending motion of the beam. The method may comprise determining an amplitude and/or a phase of the oscillation of the beam and generating feedback signals that control the motion of the beam to keep the amplitude and/or the phase of the oscillation constant. Furthermore, the method may comprise moving the beam with respect to the sample and to output the feedback signals generated upon that movement.

Beams according to the present disclosure may also be denoted as cantilevers.

### DRAWINGS

Exemplary embodiments and functions of the present disclosure are described herein in conjunction with the following drawings, showing schematically:

FIG. 1 a side view of a micromechanical beam according to the prior art;

FIG. 2 a cross-sectional view of the micromechanical beam shown in FIG. 1;

FIG. 3 a first embodiment of a micromechanical beam according to the present disclosure;

FIG. 4 a cross-sectional view of the micromechanical beam shown in FIG. 3;

FIG. 5 a further cross-sectional view of the micromechanical beam shown in FIG. 3;

FIG. 6 a perspective view of another embodiment of a micromechanical beam according to the present disclosure;

FIG. 7 a cross-sectional view of an embodiment of a micromechanical beam according to the present disclosure;

FIG. 8 a bending of a micromechanical beam without a reinforcement structure;

FIG. 9 a bending of a micromechanical beam with a reinforcement structure;

FIG. 10 a detailed top view of a readout region of the micromechanical beam according to the present disclosure;

FIG. 11 a stress induced in a readout region of a mechanical beam having a rectangular cross section;

FIG. 12 a differential output voltage of the readout structure as a function of a deflection of the micromechanical beam according to the present disclosure;

FIG. 13 a differential output voltage of the readout structure as a function of a deflection of the micromechanical beam having the rectangular cross section;

FIG. 14 a response of an output voltage of the readout structure to an instantaneous deflection of the micromechanical beam according to the present disclosure as a function of time;

FIG. 15 a first precursor structure obtained by a method for fabricating the micromechanical beam according to the present disclosure;

FIG. 16 a second precursor structure obtained by the method for fabricating the micromechanical beam according to the present disclosure;

FIG. 17 a third precursor structure obtained by the method for fabricating the micromechanical beam according to the present disclosure;

FIG. 18 a fourth precursor structure obtained by the method for fabricating the micromechanical beam according to the present disclosure;

FIG. 19 a fifth precursor structure obtained by the method for fabricating the micromechanical beam according to the present disclosure;

FIG. 20 a sixth precursor structure obtained by the method for fabricating the micromechanical beam according to the present disclosure;

FIG. 21 a seventh precursor structure obtained by the method for fabricating the micromechanical beam according to the present disclosure;

FIG. 22 an array comprising four of the micromechanical beams according to the present disclosure;

FIG. 23 another embodiment of a micromechanical beam according to the present disclosure;

FIG. 24 a cross section perpendicular to a longitudinal direction of an alternative embodiment of the micromechanical beam according to the present disclosure;

FIG. 25 a plan view of a further embodiment of a micromechanical beam according to the present disclosure;

FIG. 26 a cross section perpendicular to a longitudinal direction of a further alternative embodiment of the micromechanical beam according to the present disclosure.

### DETAILED DESCRIPTION

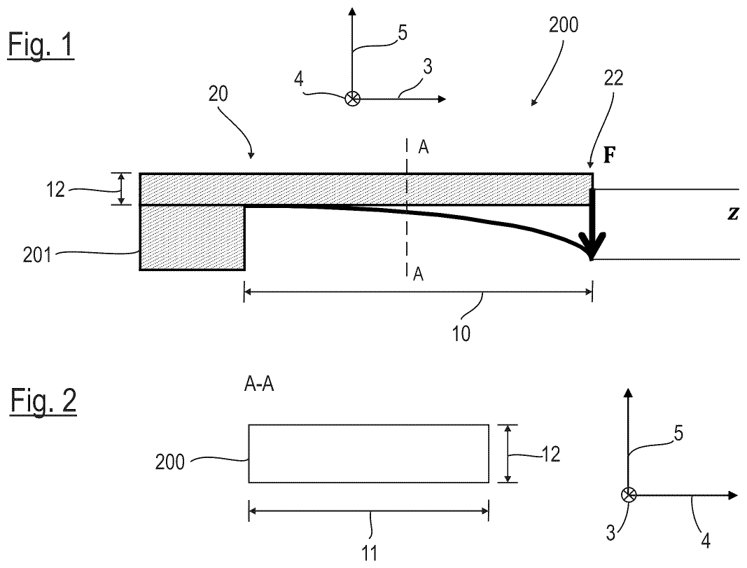

FIG. 1 depicts a side view of a micromechanical beam 200 according to the prior art and FIG. 2 shows a cross-sectional view of the micromechanical beam 200 along the line A-A indicated in FIG. 1. The micromechanical beam 200 has a free end 22 and a fixed end 20 that is fixed to a support structure 201. A freestanding section of the micromechanical beam 200 extends in a longitudinal direction 3 between the fixed end 20 and the free end 22 over a length 10.

The micromechanical beam 200 has a uniform rectangular cross-section over the length 10 with a width 11 along a width direction 4 and a height 12 along a height direction 5. The width direction 4 and the height direction 5 are orientated perpendicular to each other and also perpendicular to the length direction 3.

A force F acting on the free end 22 of the micromechanical beam 200 parallel to the height direction 5 results in a bending of the micromechanical beam 200 along the height direction 5 by a distance z. For periodic forces F, the micromechanical beam 200 oscillates around its equilibrium position.

For small amplitudes, the vibrating micromechanical beam 200 is equivalent to a spring-mass system, which is defined by its spring constant k and equivalent mass m, so that the resonance frequency is given by

$$ω = \sqrt{\frac{k}{m}} .$$

For the micromechanical beam 200, which has the rectangular cross section shown in FIG. 2, the equivalent spring constant for the first bending mode is

$${k}_{1} = \frac{F}{z} = \frac{{Ewh}^{3}}{4 {L}^{3}}$$

with L being the length 10, w the width 11, and h the height 12. E denotes Young's modulus of the beam material, which is a measure for the elasticity of the material of the micromechanical beam 200.

The static deflection z of the uniform micromechanical beam 200 for the transverse force F applied to the free end 22 can be calculated by using classical Euler-Bernouilly beam theory. For the rectangular cross section shown in FIGS. 1 and 2, the deflection z of the bending under the force load F is

$$z = \frac{F}{k} = \frac{4 {FL}^{3}}{{Ewh}^{3}} .$$

Calculation of bending forces, such as those generated when the micromechanical beam 200 approaches a probe surface with its free end 22, requires knowledge of both the mechanical properties of the beam material and the geometric arrangement of the micromechanical beam 200, also known as the second moment of area or the area moment of inertia/. The flexural stiffness of the micromechanical beam 200 is the tensor product of Young's modulus and the area moment of inertia (E×I). Young's modulus describes a material property and is constant over the length 10 of the micromechanical beam 200. For the micromechanical beam 200 with constant rectangular cross section, also called rectangular beam in the following, the second moment of area is

$$I = \frac{{wh}^{3}}{12}$$

and the flexural stiffness is

$$S = E \cdot I = \frac{{Ewh}^{3}}{12} .$$

Brownian motion causes spontaneous oscillations of the micromechanical beam 200, such that each oscillatory mode of the micromechanical beam 200 has the same average thermal energy k_{B}T. These thermal fluctuations are referred to as the thermomechanical noise. The resulting oscillatory motion as a function of time may be Fourier transformed to obtain the power spectral density (PSD) of the motion in the frequency domain. For example, Brownian motion of the micromechanical beam 200 in air is caused by surrounding molecules transferring random momentum to the micromechanical beam 200.

Expressing the dynamics of the micromechanical beam 200 as a harmonic oscillator having the total system energy, the average value of the kinetic and potential energy terms are both

$$\frac{1}{2} {k}_{B} T$$

according to the equipartition theorem, wherein T denotes temperature in Kelvin and k_{B} denotes Boltzmann's constant, k_{B}=1.3805×10⁻²³ J/K. The potential energy then equals

$$< \frac{1}{2} m {ω}_{0}^{2} {z}^{2} >= \frac{1}{2} {k}_{B} T$$

whereby ω₀=(k/m)^{1/2} is the angular resonance frequency of the micromechanical beam 200. The angular brackets indicate average values over time. Rearrangement yields the amplitude of thermal noise in the height direction 5 for the micromechanical beam 200. The spring constant k may then be determined from the temperature T and the average displacement <\hat{z}> by

$$k = \frac{{k}_{B} T}{< {\hat{z}}^{2} >} ,$$

whereas the average displacement <\hat{z}> is given by

$$< \hat{z} >= \sqrt{\frac{{k}_{B} T}{k}} = \frac{0.064 nm}{\sqrt{k}} .$$

For the micromechanical beam 200 being made from silicon and having a length 10 of 5 μm and a cross section of 100×50 nm, the mass m is about m=47×10⁻¹⁸ kg and the resonance frequency is about fᵣₑₛ≈100 MHz, the average displacement equals <z>=40 fm. The ground state energy for a beam at hundreds of MHz frequency can be equivalent to mK temperatures.

The maximum achievable scan rates are determined by the maximum achievable velocity with which the micromechanical beam 200 may be moved with respect to a sample. In the limit of low damping, this velocity is given by

$$v ≪ \frac{λ D}{2 m} .$$

In the limit of high damping, the velocity is given by

$$v ≪ \frac{λ}{2} \sqrt{\frac{k + {S}_{s}}{m} - \frac{{D}^{2}}{2 {m}^{2}} .}$$

Thereby, D denotes the damping and Ss the surface elasticity.

From these equations, it may be deduced that the maximum achievable scan speed increases if the mass of the micromechanical beam 200 is reduced, for example by making the beam micromechanical 200 smaller.

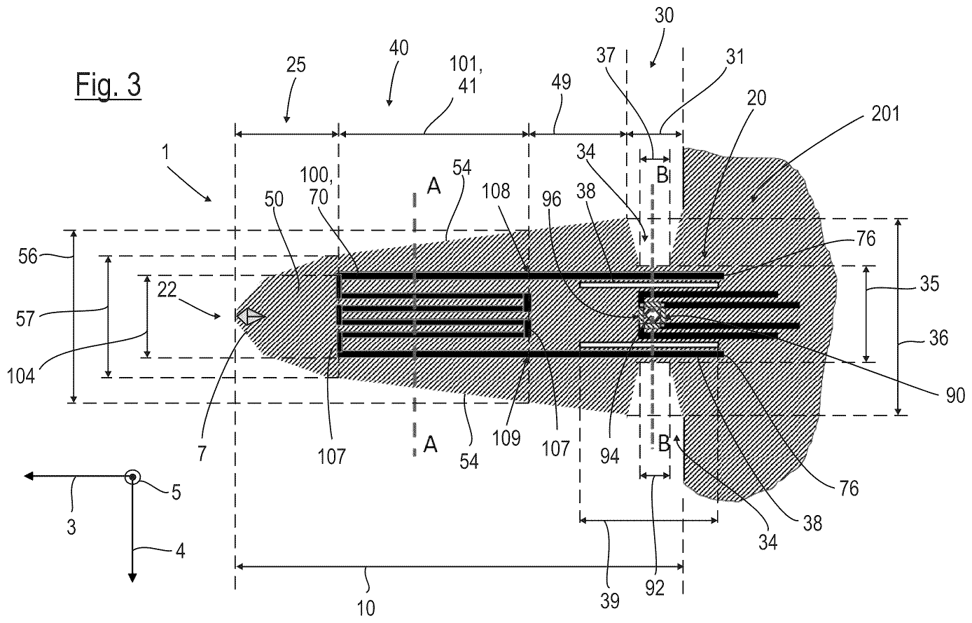

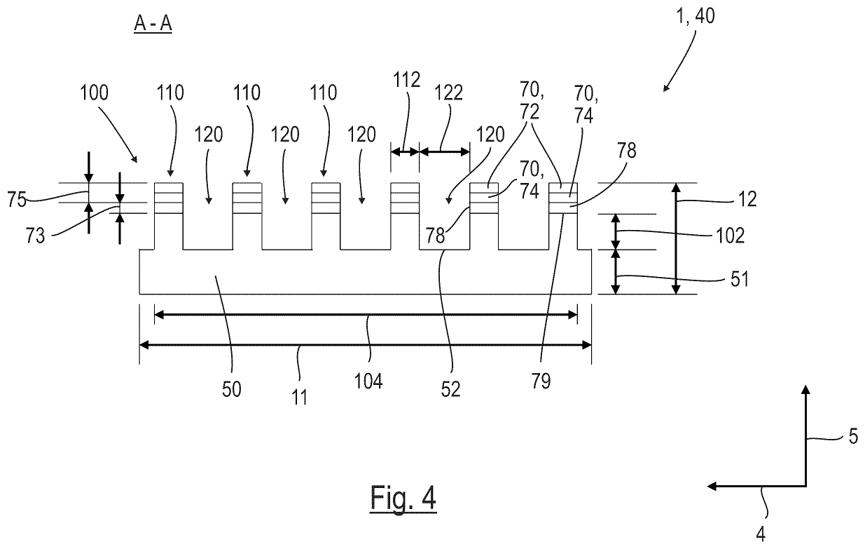

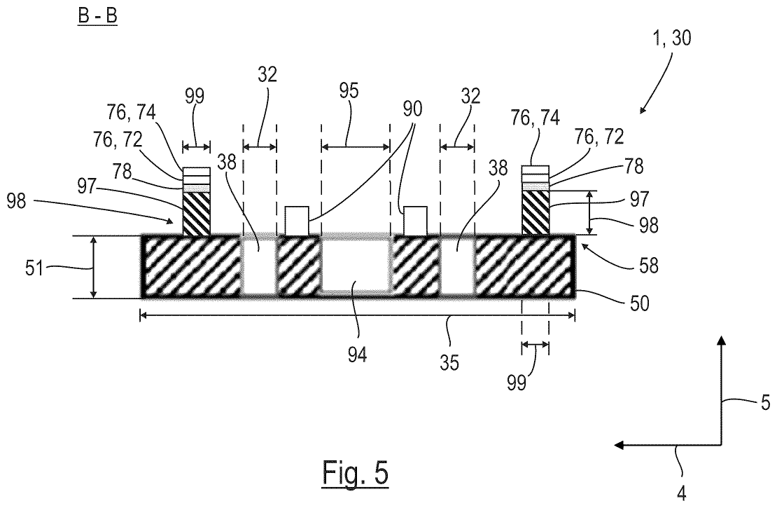

FIG. 3 depicts a first embodiment of a micromechanical beam 1 according to the present disclosure. FIG. 4 depicts a cross-sectional view of the micromechanical beam 1 perpendicular to a longitudinal direction 3 along the line A-A shown in FIG. 3 and FIG. 5 depicts a further cross-sectional view of the micromechanical beam 1 perpendicular to the longitudinal direction 3 along the line B-B shown in FIG. 3. As far as no differences are disclosed, the micromechanical beam 1 is configured as it is disclosed for the micromechanical beam 200 shown in FIGS. 1 and 2 and vice versa.

Like the beam 200, the micromechanical beam 1 extends over a length 10 between a fixed end 20 and a free end 22 parallel to the longitudinal direction 3. The fixed end 20 is materially integrally connected to a support structure 201. At the free end 22, the micromechanical beam 1 comprises a probe structure 7 that is configured as a tip that protrudes in a height direction 5 from the micromechanical beam 1 and that is located within a probe section 25 of the micromechanical beam 1. The height direction 5 is perpendicular to the longitudinal direction 3. Furthermore, the height direction 5 and the longitudinal direction 3 are perpendicular to a width direction 5.

The micromechanical beam 1 comprises a base element 50 that extends from the fixed end 20 to the free end 22. The base element 50 is configured as a plate that has a height 51 in the height direction 5 that is smaller than the length 10 parallel to the length direction 3 and a width 11 of the base element 50 parallel to the width direction 4. The base element 50 is made from silicon and formed as a single materially uniform one-piece element. The probe structure 7 is placed on a surface 52 of the base element 50 at the free end 22.

Directly at the support structure 201, the micromechanical beam 1 comprises a bending section 30 that has a length 31 parallel to the longitudinal direction 3. Between the bending section 30 and the free end 22, the micromechanical beam 1 comprises a reinforcement section 40 that extends over a length 41 parallel to the longitudinal direction 3. The reinforcement section 40 thereby is located at a distance 49 from the bending section 30. The width 11 of the base element 50 within the reinforcement section 40 tapers down towards the free end 22 of the micromechanical beam 1 from a maximum width 56 to a minimum width 57. With the embodiment shown in FIG. 3, the base element 50 comprises straight edges 54 in the region between the maximum width 56 and the minimum width 57.

Within the reinforcement section 40, the micromechanical beam 1 comprises a reinforcement structure 100. As can be seen from FIG. 4, the reinforcement structure 100 is placed on the surface 52 of the base element 50 that also carries the probe structure 7. The reinforcement structure 100 is materially uniform joined to the base element 50. The base element 50 and the reinforcement structure 100 therefore form a single piece.

The reinforcement structure 100 comprises several longitudinal ridges 110 that run parallel to each other along the longitudinal direction 3 and that are alternately joined with each other at their longitudinal ends 107 to form a meandering structure. The structure extends from a first end 108 to a second end 109.

As can be seen from FIG. 4, the ridges 110 have an essentially rectangular cross section in a plane perpendicular to the longitudinal direction 3, whereby the ridges 110 have a height 102 along the height direction 5 and a width 112 along the width direction 4. Furthermore, the ridges 110 are spaced by a distance 122 from each other along the width direction 4, so that gaps 120 are formed in between the individual ridges 110. In general, the height 102 of the reinforcement structure 100 is between 0.25 times and 5 times the height 51 of the base element 50.

The reinforcement structure 100 has a length 101 along the longitudinal direction 3 and a width 104 parallel to the width direction 4. The length 101 of the reinforcement structure 100 equals the length 41 of the reinforcement section 40. The width 104 of the reinforcement structure 100 is smaller than the width 11 of the base element 50 within the reinforcement section 40.

The length 101 of the reinforcement structure 100 is 0.5 times the length 10 of the micromechanical beam 1. In general, the length 101 of the reinforcement structure 100 may be between 0.25 times and 0.8 times, such as between 0.4 and 0.6 times the length 10 of the micromechanical beam 1.

The width 104 of the reinforcement structure 100 equals 0.9 times the minimum width 57 of the micromechanical beam 1 within the reinforcement section 40. In general, the width 104 of the reinforcement structure 100 may be between 0.5 times and 1 time, such as between 0.8 times and 0.95 times, the minimum width 57 of the micromechanical beam 1 within the reinforcement section 40. The width 104 of the reinforcement section 100 equals 0.6 times a maximum lateral width 36 of the micromechanical beam 1. In general, the width 104 of the reinforcement section 100 may be between 0.3 times and 0.8 times, such as between 0.5 times and 0.7 times, the maximum lateral width 36.

At a top surface 79 of the reinforcement structure 100, which top surface 79 faces away from the base element 50, the micromechanical beam 1 comprise a drive structure 70 that is separated from the reinforcement structure 100 by an insulating layer 78. The insulating layer 78 has a height 73 that is smaller than the height 51 of the base element 50. For example, the height 73 of the insulating layer 78 may be between 0.1 and 0.5 times, such as 0.3 times the height 51 of the base element 50.

The drive structure 70 has a height 75 that is smaller than the height 51 of the base element 50. For example, the height 75 of the drive structure 70 may be between 0.1 and 0.3 times, such as 0.2 times the height 51 of the base element 50.

The drive structure 70 is made from metal and constitutes a metal structure. It comprises a first metal layer 72 that is located next to the insulating layer 78 and a second metal layer 74 that is located on the first metal layer 72 at a side opposing the insulating layer 78. The drive structure 70 is configured as a thermomechanical actuator and the first metal layer 72 and the second metal layer 74 have differing thermal expansion coefficients.

The drive structure 70 is configured to be resistively heated by an electrical current flowing through the meandering drive structure 70. Upon heating of the drive structure 70, the first and second metal layers 72, 74 expand by different amounts so that the drive structure 70 and thus also the micromechanical beam 1 bend along the height direction 5.

A total height 12 of the micromechanical beam 1 within the reinforcement section 40 is the sum of the height 51 of the base element 50, the height 102 of the reinforcement structure 100, the height 73 of the insulating layer 78 and the height 75 of the drive structure 70. The insulating layer 78 can also be an acrylic layer or a parylene layer.

For connecting the drive structure 70 to an electrical power source, the drive structure 70 comprises two leads 76 that extend from the reinforcement section 40 through the bending section 30 to the support structure 201. As can be seen from FIG. 5, the leads 76 have a width 99 parallel to the width direction 4. The width 99 thereby is larger than the width 112 of the ridges 110 of the reinforcement structure 100.

The probe section 25, the reinforcement section 40 and the bending section 30 are separated from each other along the longitudinal direction 3 and located next to each other along the longitudinal direction 3.

As can be seen from FIG. 5, the leads 76 each are located on top of a reinforcing element 97. The reinforcing elements 97 are materially uniformly joined to the base element 50 so that the reinforcing elements 97 and the base element 50 form a one-pieced member. The reinforcing elements 97 have a height 98 that equals the height 102 of the reinforcement structure 100. The reinforcing elements 97 are configured as individual ridges that run parallel to the longitudinal direction 3 within an edge region 58 of the base element 50. The leads 76 are separated from the reinforcing elements 97 by the insulating layer 78.

With the embodiment shown in FIG. 5, the leads 76 also feature the first and second metal layer 72, 74 made from differing materials. With other embodiments, the leads 76 may also comprise a single metal layer.

Within the bending section 30, the micromechanical beam 1 comprises a readout structure 90. The readout structure 90 is placed in a readout region 96, whereby the readout region 96 is located at the center of the micromechanical beam 1 along the width direction 4.

At the center of the readout structure 90, the base element 50 comprises an opening 94 that is configured as a through hole through the base element 50. The opening 94 has a width 95 parallel to the width direction 4 that amounts to 0.5 times the height 51 of the base element 50. In general, the width 95 of the opening 94 may be between 0.25 times and one time the height 51 of the base element 50.

On either side of the readout structure 90, the base element 50 comprises an opening 38. Each opening 38 is configured as a longitudinal slot that is orientated parallel to the longitudinal direction 3. The individual openings 38 are located in between an edge of the base element 50 that delimits the base element 50 in the width direction 4 and the readout structure 90. The openings 38 extend along the entire readout region 96. The individual openings 38 have a length 39 parallel to the longitudinal direction 3 and a width 32 parallel to the width direction 4. The width 32 of the openings 38 amounts to 0.5 times the height 51 of the base element 50. In general, the width 32 may be between 0.25 times and one time the height 51 of the base element 50.

At both lateral sides of the base element 50 in the width direction 4, the base element 50 comprises a cutout 34. The cutouts 34 narrow the width 11 of the base element 50 in the bending region 32 from the maximum lateral width 36 to a minimum lateral width 35. The minimum lateral width 35 is 0.7 times the maximum lateral width 36. In general, the minimum lateral width 35 may be between 0.4 times and 0.9 times, such as between 0.6 times and 0.8 times the maximum lateral width 36.

The length of the cutouts 34 at a lateral position that corresponds to the maximum width 36 equals the length 31 of the bending region 30. The base element 50 is narrowed down to the minimum width 35 over a length 37 within the cutouts 34. The length 37 thereby is at least equal to a length 92 of the readout structure 19 parallel to the longitudinal direction 3.

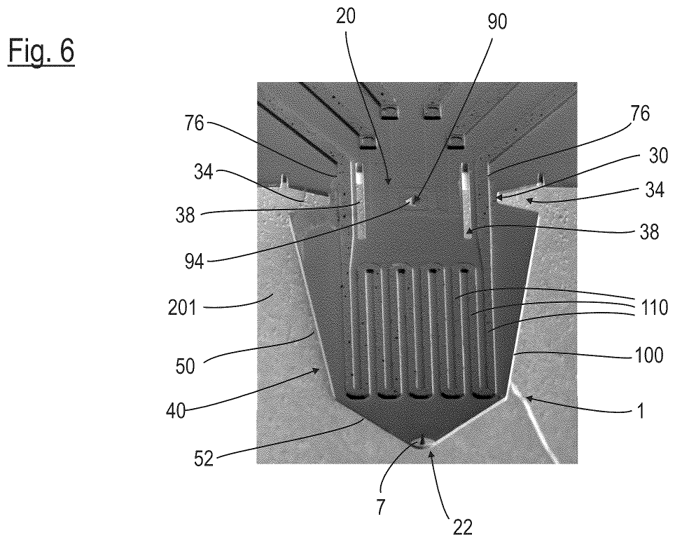

FIG. 6 shows a perspective view of another embodiment of the micromechanical beam 1 according to the present disclosure. As far as no differences are disclosed, the embodiment shown in FIG. 6 is configured as it is disclosed for the embodiment shown in FIGS. 3 to 5 and vice versa. While the reinforcement structure 100 of the micromechanical beam 1 shown in FIGS. 3 to 5 comprises six of the ridges 110, the reinforcement structure 100 of the micromechanical beam 1 shown in FIG. 6 comprises ten of the ridges 110.

As can be seen from FIG. 6, the support structure 201 is located at a surface of the base element 50 that opposes the surface 52 carrying the reinforcement structure 100 and the probe structure 7.

The micromechanical beam 1 shown in FIG. 6 has a length 10 of 165 μm, a maximum lateral width 36 of 135 μm, a minimum lateral width 35 of 115 μm and a height 51 of the base element of 1.13 μm. The height of the probe structure amounts to 6.6 μm. An effective mass density of the micromechanical beam 1 amounts to 2920 kg/m³ and the effective Young's modulus is E=150 GPa. This results in a resonance frequency of 188.1 KHz and a spring constant of k=1.2 N/m.

The width 112 of the ridges 110 is 2 μm and the width 122 of the gaps 120 is 3 μm. Furthermore, the ridges 110 have a height 102 of 4 μm. The lateral width 99 of the leads 76 amounts to 6.5 μm. Furthermore, the width 95 of the central opening 94 within the readout structure 90 is 7 μm and the width 32 of the longitudinal openings 38 is 4 μm.

In another embodiment, the micromechanical beam 1 shown in FIG. 6 has a length 10 of 350 μm, a maximum lateral width 36 of 185 μm, a minimum lateral width 35 of 140 μm and a height 51 of the base element of 1.34 μm. The height of the probe structure amounts to 6.8 μm. An effective mass density of the micromechanical beam 1 amounts to 2920 kg/m³ and the effective Young's modulus is E=150 GPa. This results in a resonant frequency of 69.12 kHz and a spring constant of k=2.29 N/m.

The width 112 of the ridges 110 is 5.2 and the width 122 of the gaps 120 is 4.8 μm. Furthermore, the ridges 110 have a height 102 of 4.5 μm. The lateral width 99 of the leads 76 amounts to 9.9 μm. Furthermore, the width 95 of the central opening 94 within the readout structure 90 is 6 μm and the width 32 of the longitudinal openings 38 is 5.2 μm.

In another embodiment, the micromechanical beam 1 may have a reinforcement structure 100 having a height 102 of 3 μm and a base element 50 having a height 51 of 3 μm. The micromechanical beam 1 then has a resonance frequency of 1800 kHz and a mechanical bandwidth of 6.4 kHz.

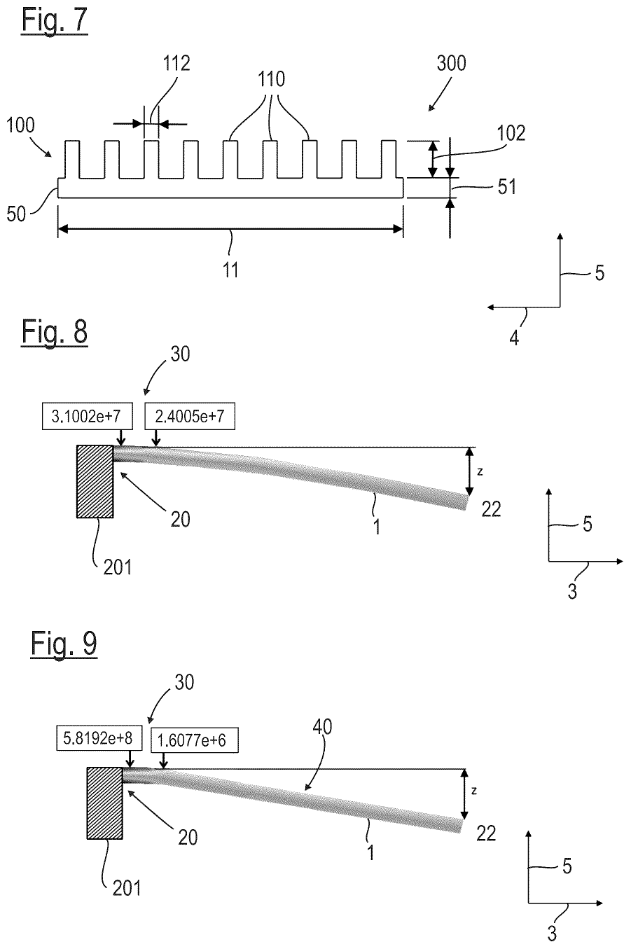

FIG. 7 depicts a cross-sectional view of an embodiment of the micromechanical beam 1 that comprises nine of the ridges 110. As far as no differences are disclosed, the embodiment shown in FIG. 7 is configured as it is disclosed for the embodiment shown in FIGS. 3 to 5 and vice versa.

A second moment of area Iᵣ of the cross section shown in FIG. 6 amounts to

$${I}_{r} = \frac{1}{6} {w}^{3} t ( 1 + 3 \frac{{h}_{t} - {h}_{p}}{w} ) - 1.125 ,$$

with w denoting the width 104 of the reinforcement structure 100, t the width 112 of the ridges 110, hₜ the height 102 of the reinforcement structure 100 and hp the height 51 of the base element 50.

FIGS. 8 and 9 illustrate the effect of the reinforcement structure 100 on the stress induced within the bending section 30 for the micromechanical beams 1 according to the present disclosure. FIG. 8 thereby shows bending of the micromechanical beam 1 without the reinforcement structure 100 when being deflected by a distance z in the height direction 5 and FIG. 9 shows bending of the micromechanical beam 1 with the reinforcement structure (not visible in FIG. 9) when being deflected by the distance z. The amount and distribution of the stress induced within the micromechanical beam 1 is indicated by the shading of the micromechanical beam 1. While the stress is increased by at least a factor of 18 within the bending section 30 for the micromechanical beam 1 shown in FIG. 9 compared to the micromechanical beam 1 shown in FIG. 8, the stress decreases by at least one order of magnitude further away from the bending section 30 towards the free end 22 of the micromechanical beam 1.

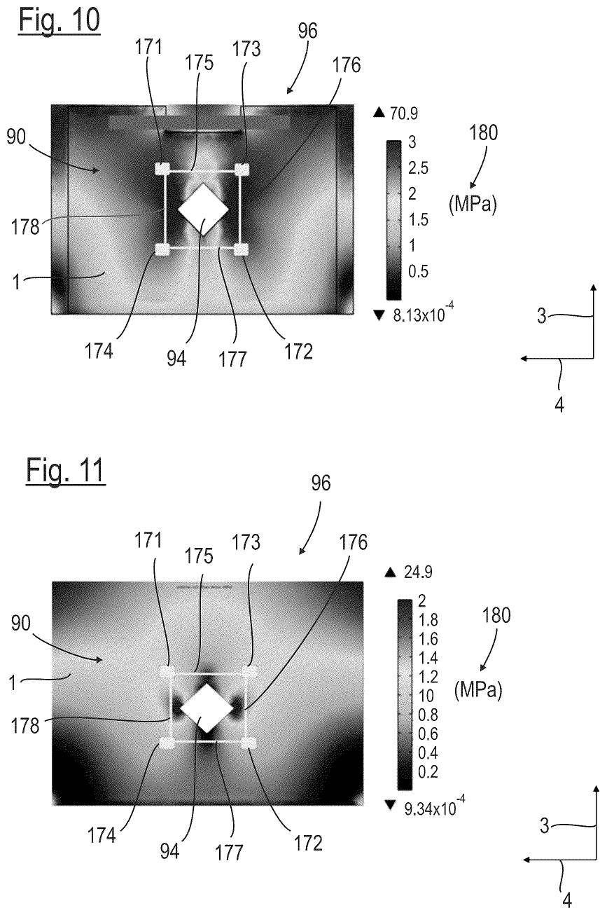

FIG. 10 shows a detailed top view of the readout region 96 with the readout structure 90. The readout structure 90 is configured as a Wheatstone bridge. It comprises a first contact 171 and a second contact 172, whereby the second contact 172 is located opposite to the first contact 171 with respect to the opening 94 within the micromechanical beam 1. The first and second contact 171, 172 thereby are located at opposing sides of the rectangular opening 94.

The readout structure 90 furthermore comprises a third contact 173 and a fourth contact 174. The third and fourth contact 173, 174 are located at the remaining opposing sides of the opening 94. The third contact 173 is electrically coupled in between the first contact 171 and the second contact 172. A first resistor 175 connects the first contact 171 to the third contact 173 and a second resistor 176 connects the second contact 172 to the third contact 173. Furthermore, the fourth contact 174 is electrically coupled in between the first contact 171 and the second contact 172 in parallel to the third contact 173. Thereby, a third resistor 177 connects the fourth contact 174 to the second contact 172 and a fourth resistor 178 connects the fourth contact 174 to the first contact 171.

The second resistor 176 and the fourth resistor 178 thereby are orientated parallel to the longitudinal direction 3 and the first resistor 175 and the third resistor 177 are orientated parallel to the width direction 4. The resistors 175, 176, 177, 178 are configured as piezoresistive elements that have a resistance that changes with the stress induced in the resistors 175, 176, 177, 178.

The first contact 171 is connected to ground and the second contact 172 is connected to a voltage line for connection to a voltage source providing an operating voltage of the readout structure 90. The third contact 173 is connected to a first sensing line for connection to a first input of a readout module configured to determine the resistance of the readout structure 90. The fourth contact 174 is connected to a second sensing line for connection to a second input of the readout module.

As can be seen from FIG. 10, the stress 180, which is indicated by the shading of the beam 1 in FIG. 10, is concentrated along the resistors 175, 176, 177, 178 of the readout structure 90.

FIG. 11 depicts, for comparison, the stress 180 induced in the readout region 96 for a micromechanical beam 1 that has a rectangular cross section perpendicular to the longitudinal direction 3 and that does not feature the reinforcement structure 100, the cutouts 34 within the bending region 30 and the taper from the maximum width 36 to the minimum width 57. As can be seen from FIG. 11, the stress 180 induced in the readout region 96 around the readout structure 90 is smaller than the stress 180 induced in the micromechanical beam 1 according to the present disclosure and shown in FIG. 10.

The sensitivity of the piezoresistive read-out structure 90 is defined as the slope of the characteristic output curve

$$\frac{dV}{dz} ,$$

which is defined as an output voltage change dV for a given deflection dz due to load force. It furthermore denotes a minimum input of beam deflection generated by a standardized force load that will generate a measurable output voltage or the minimum load-force required to generate a measurable output voltage.

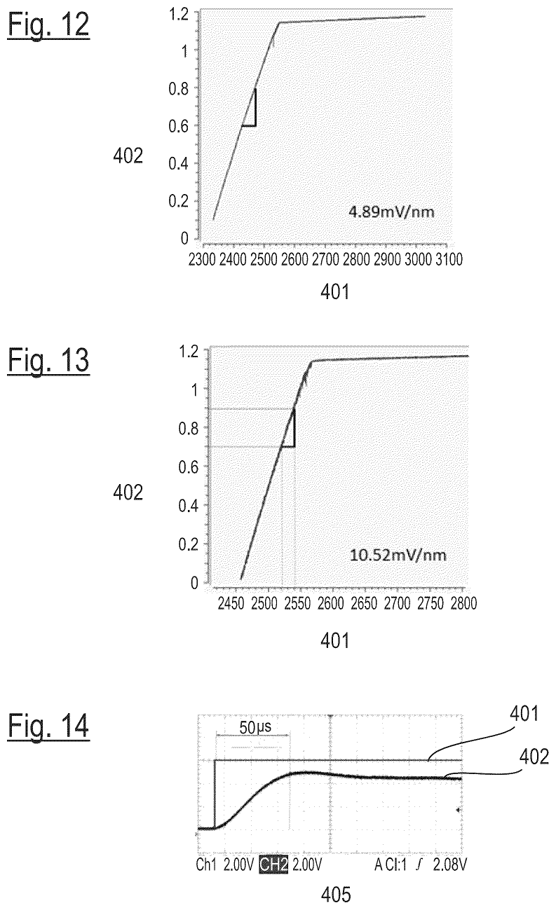

FIG. 12 depicts a differential output voltage 402 of the readout structure 90 as a function of a deflection 401 of the micromechanical beam 1 shown in FIG. 11 and FIG. 13 depicts the differential output voltage 402 of the readout structure 90 as a function of the deflection 401 of the micromechanical beam 1 according to the present disclosure, as shown in FIG. 10. As can be seen from these Figures, the micromechanical beam 1 according to the present disclosure as a sensitivity or characteristic output curve of

$$\frac{d V}{dz} = 10.52 mV / nm ,$$

while the micromechanical beam 1 shown in FIG. 11 as a sensitivity or characteristic output curve of

$$\frac{d V}{dz} = 4.89 mV / nm .$$

A piezoresistive read-out response time is defined as the time required for the differential output voltage measured at the sensing lines of the piezoresistive readout structure 90 to change from an initial value to a value within a tolerance band around a settled final voltage value.

FIG. 14 depicts the response of the output voltage 402 of the readout structure 90 to an instantaneous deflection 401 of the micromechanical beam 1 according to the present disclosure as a function of time 405. The micromechanical beam 1 thereby is deflected by applying a step-formed DC voltage to the leads 76 of the drive structure 70. An effective deflection of the micromechanical beam 1 in the height direction 5 thereby is about 1200 nm and a spring constant of the micromechanical beam amounts to 2.85 N/m. As can be seen from FIG. 14, the readout response time is smaller than 20 μs, which results in a bandwidth of more than 20 KHz. If a force applied to the micromechanical beam 1 is less than 10 nN upon activation of an oscillatory motion in the height direction 5, the readout structure 90 has a step-like response time of about 50 μs.

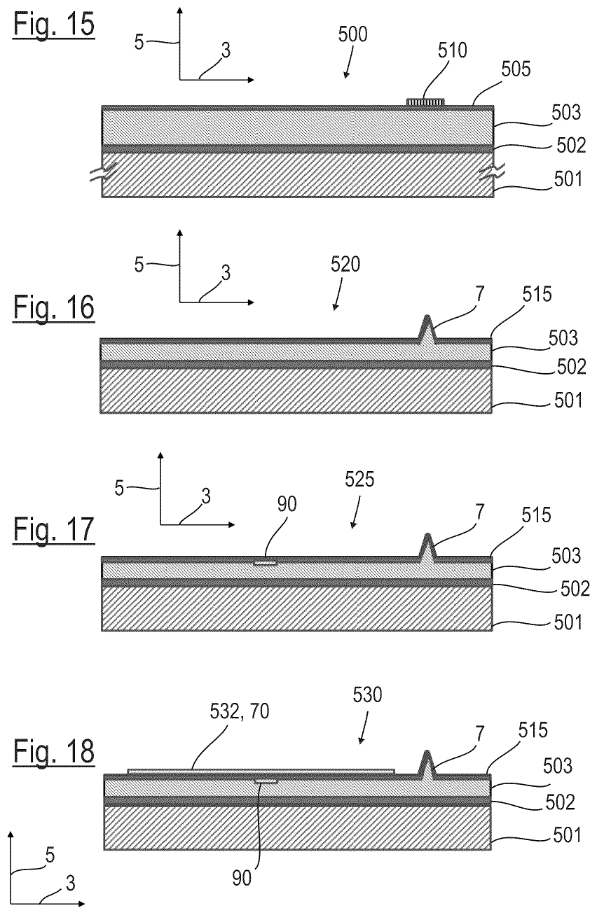

FIG. 15 depicts a first precursor structure 500 obtained while performing a method for fabricating the micromechanical beam 1 according to the present disclosure.

The method comprises providing a base structure comprising a base layer 501, an insulating layer 502 located on top of the base layer 501 in the height direction 5 and a beam layer 503, which is located on top of the insulating layer 502 in the height direction 5. The base structure is configured as a silicon-on-insulator (SOI) waver. The base layer 501 and the beam layer 503 are made from silicon and the insulating layer 502 is configured as an oxide layer.

The base structure then is provided with a further insulating layer 505 placed on top of the beam layer 503. The further insulating layer 505 is configured as an oxide layer.

The insulating layer 502 is configured as a buried oxide layer having a height of 300 nm the height direction 5 and the beam layer 503 has a height of 15 μm. The backside of the base layer 501 that faces away from the beam layer 503 is covered with 60 nm CVD silicon nitride. The further insulating layer 505 is configured as thermal SiO2 having a height of 300 nm.

The probe structure 7 is formed by a micromachining process. This process comprises applying a probe mask 510 onto the further insulating layer 505 and structuring the probe mask 510 by lithography. This results in the first precursor structure shown in FIG. 15.

The probe mask 510 has a height of 1 μm.

The probe structure 7 then is defined by etching, such as by RIE etching and/or wet etching, the beam layer 503. Thereby, the probe structure 7 is defined by undercuts forming underneath the probe mask 510 within the beam layer 503.

During the step of etching, a pattern of the probe mask is transferred by wet etching into the insulating layer 505 and in the following step the probe structure 7 is formed by wet etching, for instance in water hot-solution of potassium hydroxide (KOH) or tetramethylammonium hydroxide (TMAH).

After forming the probe structure 7, a protective layer 515 is formed on the beam layer 503 and the probe structure 7 to preserve the probe structure 7 during subsequent processing. The protective layer acts as a layer of passivation. The protective layer 515 is configured as a SiO2/Si3N4 layer. The protective layer 515 has a height of 150 nm. It is configured as a zero-stress Si3N4 layer. The protective layer 515 is formed by plasma enhanced chemical vapor deposition and passivates the upper side of the base structure.

This results in this second precursor structure 520 shown in FIG. 16.

FIG. 17 shows a third precursor structure 525 obtained by the method for fabricating the micromechanical beam 1 according to the present disclosure.

The third precursor structure 525 is formed from the second precursor structure 520 by applying a patterned photoresist on top of the protective layer 515. Furthermore, electrical connections to the readout structure 90 are defined by implanting charge carriers into the beam layer 503. The protective layer 515 and the patterned photoresist are thereby used as a mask for implanting the carriers. Implanting is performed as boron implantation at 30 keV. Afterwards, the patterned photoresist is removed. This is performed by microwave O2-plasma stripping, followed by an annealing process at 1050 C for 30 min.

The method then comprises defining the resistors 175, 176, 177, 178 of the readout structure 90. They are exemplarily defined by boron implantation at 20 keV in ultrahigh vacuum with subsequent rapid thermal annealing (RTA) at 1100° C. for 30 s. Alternatively, the resistors 175, 176, 177, 178 may be defined by implantation and annealing.

In a subsequent step of lithography, contact holes are defined and etched in the protective layer 515 to allow for connection of p+ diffusion regions with metal paths. Etching is performed as a plasma etching process.

After performing these steps of the method, the third precursor structure 525 shown in FIG. 17 is obtained.

FIG. 18 depicts a fourth precursor structure 530 obtained when performing the method for fabricating the micromechanical beam 1.

The fourth precursor structure 530 is obtained from the third precursor structure 525 by depositing a metal layer 532 on top of the protective layer 515. The metal layer 532 is deposited by magnetron sputtering. It has a height of 800 nm. The metal layer 532 is configured as an Al/Si/Mg thin film.

The method then comprises defining the drive structure 70 from the metal layer 532. The drive structure 70 is defined by lithography for defining a mask of photoresist and subsequent metal etching. The step of defining the drive structure 70 also comprises defining the leads 76. The leads 76 also are defined by lithography and subsequent metal etching. Furthermore, the method comprises defining, by lithography and subsequent metal etching, bonding parts for connecting the micromechanical beam 1 to a control system.

Subsequently, an annealing step in N2 atmosphere at 410° C. for 50 min is carried out.

The method then yields the fourth precursor structure 530 shown in FIG. 18.

Subsequently, a further protective layer is deposited. The further protective layer is configured as a low-stress oxide-nitride layer. It is deposited by plasma-enhanced chemical vapour deposition (PECVD).

In a further step, the reinforcement structure 100 is defined. The reinforcement structure 100 is defined by etching the beam layer 503. A mask for etching the reinforcement structure 100 is thereby defined by the drive structure 70, which provides a patterned metal film as a hard mask. With other embodiments of the method, the mask of photoresist used for defining the drive structure 70 may still be present when performing the step of defining the reinforcement structure 100.

Alternatively, a separate mask for etching the reinforcement structure 100 may also be formed by lithography. For example, the mask may be formed by a patterned photoresist.

Etching of the reinforcement structure 100 is performed as dry etching. It comprises removing the further protective layer in a FH3/Ar gas mixture. Silicon etching of the beam layer 503 is subsequently performed by a so-called gas-chopping process. During etching, the beam layer 503 is thinned except for the regions masked by the etch mask. The etch mask also is used also for protecting the probe structure 7 during etching.

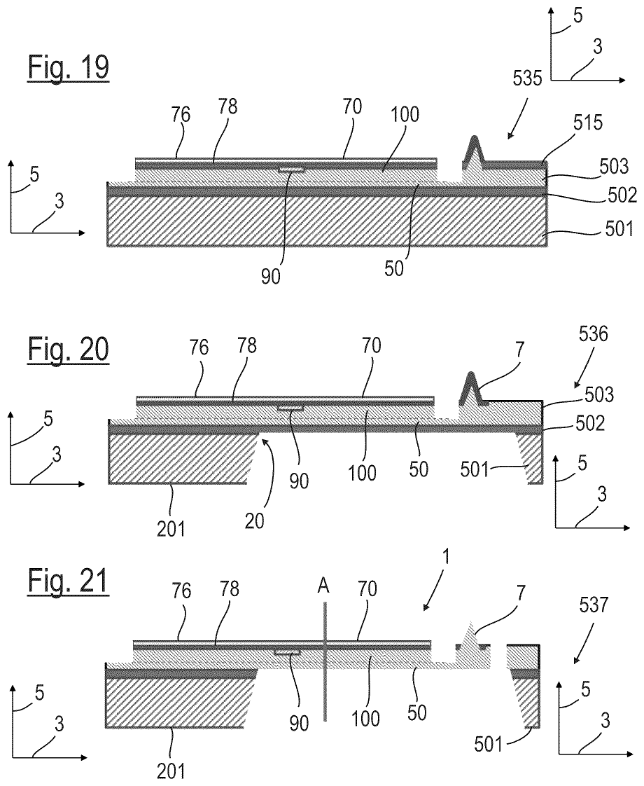

This results in a fifth precursor structure 535 shown in FIG. 19.

Subsequently, the base element 50 is defined by removing the base layer 501 in the area occupied by the freestanding portion of the micromechanical beam 1. This comprises a step of preforming lithography at the backside of the base layer 501 to define the freestanding portion. Subsequently, the base layer 501 is etched to create a membrane comprising the freestanding portion of the micromechanical beam 1. Etching first is performed as wet etching of the CVD silicon nitride at the backside of the base layer 501. This is followed by etching of the base layer 501 with deep, anisotropic silicon etching. Etching is performed in water hot-solution of potassium hydroxide (KOH) or tetramethylammonium hydroxide (TMAH). The etching is stopped at the insulating layer 502, which is configured as a buried SOI oxide film (BOX). The lithography at the backside of the base layer 501 is aligned with the structures placed at the frontside of the base layer 501 to obtain the required beam design. The remainder of the base layer 501 located at the fixed end 20 of the micromechanical beam 1 forms the support structure 201.

This results in the sixth precursor structure 536 shown in FIG. 20.

The method then comprises defining the micromechanical beam 1. This involves a step of lithography on the top surface and a subsequent step of dry etching. An outline of the micromechanical beam 1 is defined in the next lithography step and a dry etching step. During etching, the BOX and oxide protecting the probe structure 7 are stripped using HF vapor etch.

A final step of microwave plasma stripping removes the resist of the last lithography step. This results in the sixth precursor structure 536 shown in FIG. 21.

Subsequently, the micromechanical beam 1 including the support structure 201 is mechanically separated from the remainders of the base layer 501.

With all embodiments, the micromechanical beam 1 will may also be part of an array of several of the micromechanical beams 1. With these embodiments, the array of the micromechanical beams 1 is fabricated in parallel and mechanically separated from the remaining silicon frame.

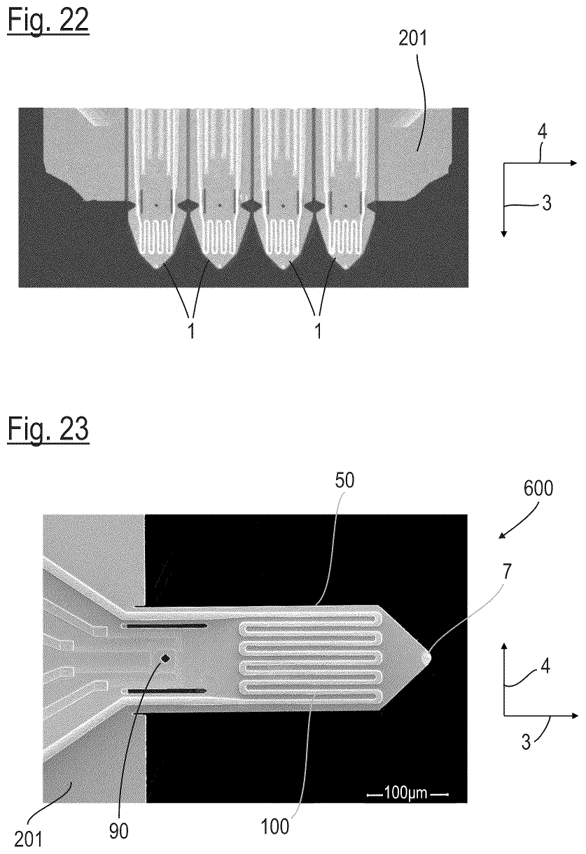

FIG. 22 shows such an array comprising four of the micromechanical beams 1 arranged next to each other in the width direction 4. The micromechanical beams 1 are connected via the support structure 201.

Each of the micromechanical beams 1 shown in FIG. 22 has a length 10 of 91 μm, a maximum lateral width 36 of 56 μm, a minimum lateral width 35 of 41 μm and a height 51 of the base element of 1.8 μm. The height of the probe structure amounts to 5.6 μm. An effective mass density of the micromechanical beam 1 amounts to 2920 kg/m³ and the effective Young's modulus is E=150 GPa. This results in a resonant frequency of 1.21 MHz and a spring constant of k=1.24 N/m.

The width 112 of the ridges 110 is 2.3 μm and the width 122 of the gaps 120 is 2.1 μm. Furthermore, the ridges 110 have a height 102 of 3.7 μm. The lateral width 99 of the leads 76 amounts to 5.6 μm. Furthermore, the width 95 of the central opening 94 within the readout structure 90 is 5.2 μm and the width 32 of the longitudinal openings 38 is 3.2 μm.

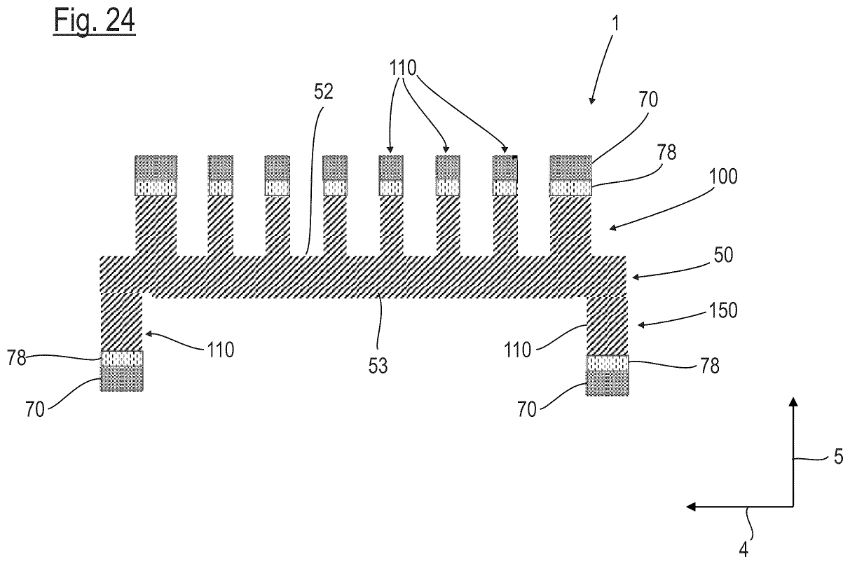

FIG. 23 shows another embodiment of a micromechanical beam 600 according to the present disclosure. As far as no differences are disclosed, the micromechanical beam 600 is configured as it is disclosed for the micromechanical beam 1 and vice versa. The micromechanical beam 600 comprises a base element 50 that has straight edges along the longitudinal direction 3 and thus does not feature the taper from the maximum width 36 to the minimum with 57.

FIG. 24 shows a cross section perpendicular to the longitudinal direction 3 of an alternative embodiment of the micromechanical beam 1. As far as no differences are disclosed, the micromechanical beam 1 shown in FIG. 24 is configured as it is disclosed for the other micromechanical beams 1, 600 according to the present disclosure and vice versa. In addition to the reinforcement structure 108 the surface 52 of the base element 50, the micromechanical beam 1 comprises a further reinforcement structure 150. As far as no differences are disclosed, the further reinforcement structure 150 is configured as it is disclosed for the reinforcement structure 100 and vice versa.

The further reinforcement structure 150 is located at a further surface 53 of base element 50, whereby the further surface 53 is located opposite the surface 52 in the height direction 5. The further reinforcement structure 150 comprises the ridges 110, whereby the ridges 110 of the further reinforcement structure 150 extend in an opposite direction from the surface 53 as the ridges 110 of the reinforcement structure 100 extend from the surface 52.

The further reinforcement structure 150 comprises two of the ridges 110. The ridges 110 are located at the edges of the base element 50 in the width direction 4. The ridges 110 thereby run parallel to the longitudinal direction 3. Like the ridges 110 of the reinforcement structure 100, the ridges 110 of the further reinforcement structure 150 carry a metal layer 70 that is separated from the ridges 110 by an insulating layer 78. The metal layer 70 and insulating second layer 78 are configured as it is disclosed for the corresponding layers 70, 78 placed on top of the ridges 110 of the reinforcement structure 100.

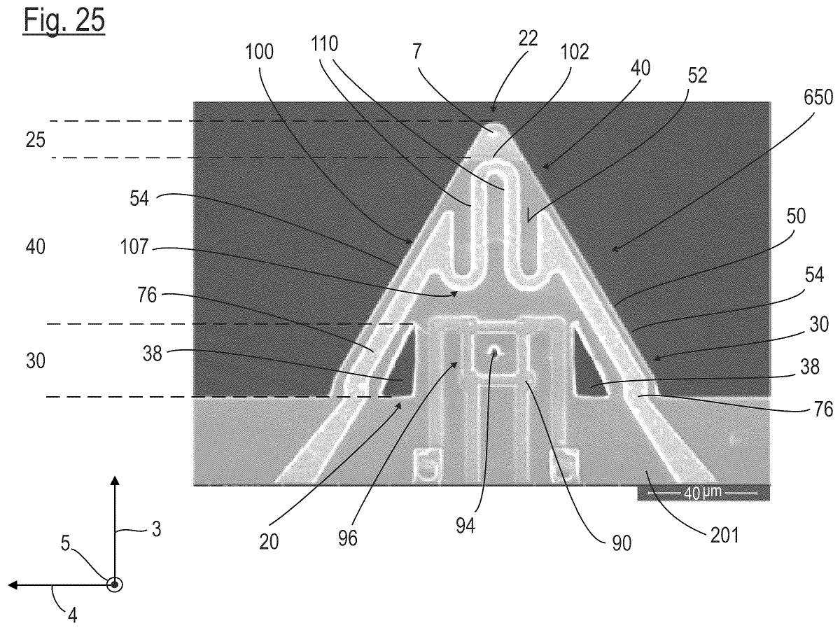

FIG. 25 depicts a plan view of a further micromechanical beam 650 according to the present disclosure. As far as no differences are disclosed, the micromechanical beam 650 is configured as it is disclosed for the micromechanical beams 1, 600 and vice versa.

The further micromechanical beam 650 comprises a triangular shape. With the present embodiment, the further micromechanical beam 650 is configured as an equilateral triangle. A baseline of the triangle is oriented parallel to the width direction 4 at the support structure 201. The probe structure 7 is located at a corner of the triangle that opposes the baseline.

The further micromechanical beam 650 comprises straight edges 54 that run from the bending section 30 up to the probe section 25. Thereby, the straight edges 54 run up to a longitudinal position of the probe structure 7 in the longitudinal direction 3. In addition, the straight edges 54 extend to a longitudinal position of the readout structure 90 in the longitudinal direction 3. The straight edges 54 thereby cover more than one half of the extent of the readout structure 96 along the longitudinal direction 3.

The openings 38 are located within the bending section 30 and in between the readout region 96 and the straight edges 54. The openings 38 have a triangular shape. With the embodiment shown, the openings 38 are configured as right-angled triangles. Respective hypotenuses of the triangles are orientated parallel to the edges 54. The further micromechanical beam 650 does not feature the lateral cutouts 34 within the bending region 30.

The further micromechanical beam 650 comprises a reinforcement structure 100 that has four of the ridges 110. Joints at the longitudinal ends 107 of the reinforcement structure 100 are curved. The joints are thereby configured as circular sections.

The micromechanical beam 650 has a length in the longitudinal direction 3 of 70 μm. The resistors of the readout structure 90 have a transverse width of 4.5 μm, and the ridges 110 have a transverse width of 5 μm. The ridges 110 have a metallization made from aluminum.

With other embodiments, the micromechanical beam 650 may also be configured without the reinforcement structure 100. In this case, it may exemplarily comprise a meandering conducting structure that connects the leads 76 in between the probe section 25 and the base element 201. Like with embodiments featuring the reinforcement structure 100, this conducting structure may then be configured as a heating element to excite oscillations of the micromechanical beam 650.

With all embodiments, the micromechanical beam 1, 600, 650 comprises a patterned multi-layer structure, whereby the patterned multi-layer structure comprises the reinforcement structure 100. The multilayer structure is homogeneously patterned in the height direction 5. The gaps 120 between the ridges 110 of the reinforcement structure 100 are formed by regions in which the multi-layer structure has been removed.

With the micromechanical beam 1 shown in FIG. 4, the multi-layer structure comprises the metal structure 70 with the first metal layer 72 and the second metal layer 74, the insulating layer 78 and a part of the base material, which part is given by the structured section of the base material on top of the surface 52 of the base element 50 in the height direction 5.

With alternative embodiments of the micromechanical beams 1, 600, 650 described before, the reinforcement structure 100 may also comprise the insulating layer 78 and/or the metal structure 70. The dimensions and material properties of the reinforcement structure 100, such as the flexural stiffness, the cross section perpendicular to the longitudinal direction 3, the second axial moment of area for bending around an axis parallel to the width direction 4, and the height 102, then may be at least partly given by the corresponding dimensions and material properties of the insulating layer 78 and/or of the metal structure 70.

With further alternative embodiments of the micromechanical beams 1, 600, 650 described before, the reinforcement structure 100 may be formed separate from the material of the base element 50 and/or the surface 52 of the base element 50 carrying the reinforcement structure 100 may be configured as a flat surface within the entire area covered by the reinforcement structure 100. The material of the base element 50 may be free from sections that are structured in the height direction 5.

For example, the reinforcement structure 100 may be free from parts that are materially uniform with the base element 50. The reinforcement structure 100 may only comprise layers with materials that are different from the material of the base element 50.

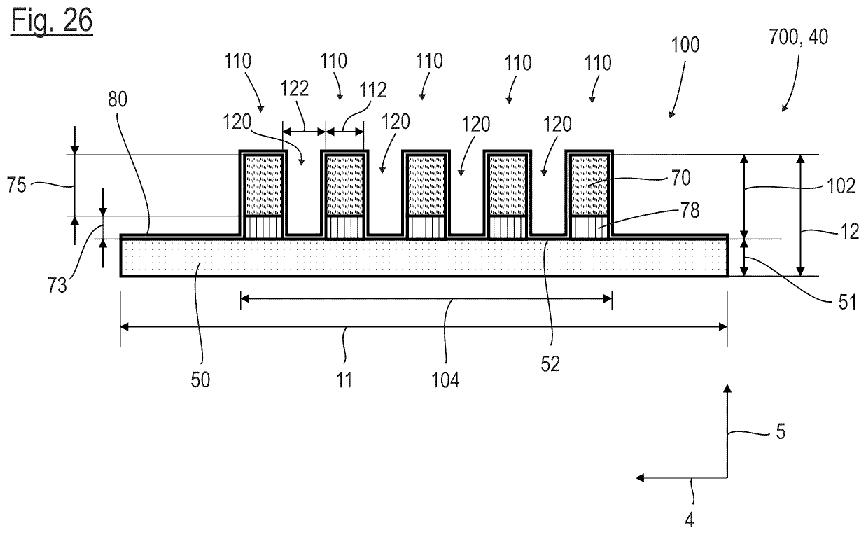

FIG. 26 shows a cross section perpendicular to the longitudinal direction 3 of a micromechanical beam 700 that is such a further alternative embodiment of the micromechanical beam 1. As far as no differences are disclosed, the micromechanical beam 700 shown in FIG. 26 is configured as it is disclosed for the other micromechanical beams 1, 600, 650 according to the present disclosure and vice versa.

With the micromechanical beam 700, the reinforcement structure 100 is made from materials that are different from the base material of the base element 50.

The reinforcement structure 100 comprises, namely consists of, a metal structure 70 and an insulating layer 78 in between the metal structure 70 and the base element 50. As far as no differences are disclosed, the metal structure 70 and the insulating layer 78 are configured as it is disclosed for the metal structure 70 and the insulating layer 78 of the micromechanical beam 1 and vice versa. With alternative embodiments, the reinforcement structure 100 may also only comprise the metal structure 70 and not the insulating layer 78. The insulating layer 78 then may be a homogeneous layer in a plane perpendicular to the height direction 5.

The metal structure 70 comprises only a single metal layer. This metal layer may be formed from or comprise tungsten, a tungsten alloy, molybdenum, a molybdenum alloy, or an aluminum-magnesium alloy. The insulating layer 78 may be formed from or comprise SiO2.

With all embodiments, the height 75 of the metal structure 70 may be between 0.7 μm and 5 μm. The height 75 may be at least 0.7 μm, at least 1 μm, at least 1.5 μm, at least 2 μm, at least 2.5 μm, at least 3 μm, at least 3.5 μm, at least 4 μm, or at least 4.5 μm. The height may be at most 1 μm, at most 1.5 μm, at most 2 μm, at most 2.5 μm, at most 3 μm, at most 3.5 μm, at most 4 μm, at most 4.5 μm, or at most 5 μm. The width 112 of the ridges of the metal structure 70 may be between 0.7 μm and 2 μm. The width 112 may be at least 0.7 μm, at least 0.8 μm, at least 1 μm, at least 1.25 μm, at least 1.5 μm, or at least 1.75 μm. The width 112 may be at most 0.8 μm, at most 1 μm, at most 1.25 μm, at most 1.5 μm, at most 1.75 μm, or at most 2 μm.

With all embodiments, the height 73 of the insulating layer 78 may be between 0.7 μm and 2 μm. The height 73 may be at least 0.7 μm, at least 0.8 μm, at least 1 μm, at least 1.25 μm, at least 1.5 μm, or at least 1.75 μm. The height 73 may be at most 0.8 μm, at most 1 μm, at most 1.25 μm, at most 1.5 μm, at most 1.75 μm, or at most 2 μm. A width of the ridges of the insulating layer 78 equals the width 112 of the ridges of the metal structure 70.

A width 122 of the gaps 120 in between the ridges 110 of the metal structure 70 may be between 1 μm and 3 μm. For example, the width 122 may be at least 1 μm, at least 1.25 μm, at least 1.5 μm, at least 1.55 μm, at least 2 μm, at least 2.25 μm, at least 2.5 μm, or at least 2.75 μm. The width 122 may be at most 1.25 μm, at most 1.5 μm, at most 1.55 μm, at most 2 μm, at most 2.25 μm, at most 2.5 μm, at most 2.75 μm, or at most 3 μm.

Alternative metal structures 70 of the other embodiments of the micromechanical beam 1, 600, 650 may also only comprise such a single metal layer.

All metal structures 70 having only a single metal layer may be configured as the drive structure. The metal structures 70 then may have a different thermal coefficient of expansion than the base element 50.

This may induce bending of the micromechanical beam 1, 600, 650 due to the different thermal coefficients of expansion of the single metal layer and the base element 50.

The micromechanical beam 700 exemplarily comprises a cover layer 80. The cover layer 80 covers the reinforcement structure 100. Furthermore, the cover layer 80 covers the entire reinforcement section 40. Additionally, the cover layer 80 exemplarily covers the entire micromechanical beam 700.

The cover layer 80 is made from a silicon nitride. Exemplarily, it is made from Si3N4. The cover layer 80 has been formed by atomic layer deposition.

The cover layer 80 has a thickness of 20 nm. Exemplarily, the thickness of the cover layer 80 is less than 10%, such as less than 5%, for example less than 3% of the thickness 75 of the metal structure 70 and/or the thickness 102 of the reinforcement structure 100.

The cover layer 80 forms a layer of passivation.

All other embodiments of the micromechanical beam 1, 600, 650 according to the present disclosure may also comprise the cover layer 80.

Fundamental benchmarks of the micromechanical beams 1, 600 according to the present disclosure are as follows: (i) radical downsizing-scalability, (ii) routinely atomic resolution, (iii) very simple in use, (iv) high operation speeds due to high bandwidth, and (v) excellent performance in any environment. In summary, micromechanical beams 1, 600 that are configured as active probes featuring a drive structure 70 are more promising for all future developments in scanning probe techniques than passive probes using optical readout. Instead of having to move a bulky sample stage, a more dynamic measuring head comprising the micromechanical beams 1, 600 only must be traveled across the sample. This fundamentally simplifies AFM architecture, which can be newly arranged in a space-saving manner.

### REFERENCE NUMERAL LIST

1 micromechanical beam
3 longitudinal direction
4 width direction
5 height direction
7 probe structure
10 length
11 width
12 height
20 fixed end
22 free end
25 probe section
30 bending section
31 length of bending section
32 width
34 cutout
35 minimum lateral width
36 maximum lateral width
37 length
38 opening
39 length
40 reinforcement section
41 length of reinforcement section
49 distance
50 base element
51 height
52 surface
53 further surface
54 edge
56 maximum width
57 minimum width
58 edge region
70 drive structure
72 first metal layer
73 height of insulating layer
74 second metal layer
75 height of drive structure
76 lead
78 insulating layer
79 top surface
80 cover layer
90 readout structure
92 longitudinal length
94 opening
96 readout region
97 reinforcing element
98 height
99 width
100 reinforcement structure
101 length
102 height
104 width
107 longitudinal end
108 first end
109 second end
110 ridge
111 height
112 width
120 gap
122 width
150 further reinforcement structure
171 first contact
172 second contact
173 third contact
174 fourth contact
175 first resistor
176 second resistor
177 third resistor
178 fourth resistor
180 stress
200 micromechanical beam
20 support structure
401 deflection
402 output voltage
405 time
500 first precursor structure
50 base material
502 insulating layer
503 beam layer
505 further insulating layer
510 probe mask
515 protective layer
520 second precursor structure
525 third precursor structure
530 fourth precursor structure
532 metal layer
535 fifth precursor structure
536 sixth precursor structure
537 seventh precursor structure
600 micromechanical beam
650 micromechanical beam
700 micromechanical beam

1-30. (canceled)

31. Micromechanical beam for scanning probe measurements, lithography and the like, the micromechanical beam extending in a longitudinal direction between a fixed end and a free end,
wherein the beam has a height along a height direction perpendicular to the longitudinal direction, the height being smaller than a width along a width direction,
wherein the beam has a bending section that is located in the longitudinal direction at the fixed end of the beam,
wherein the beam has a reinforcement section that is located in the longitudinal direction between the bending section and the free end,
wherein the beam has a base element and a reinforcement structure located on the base element in the reinforcement section,
wherein the reinforcement structure is configured to increase a flexural stiffness of the beam in the reinforcement section for bending in the height direction.

32. Micromechanical beam according to claim 31,
wherein, in the reinforcement section, the flexural stiffness of the base element with the reinforcement structure is larger, for example by at least a factor of 1.2, 2.5, 5, 8, 10, 15 or 20, than the flexural stiffness of the base element without the reinforcement structure, and/or
wherein a cross section of the base element and the reinforcement structure in a plane perpendicular to the longitudinal direction has a second axial moment of area for bending around an axis parallel to the width direction that is larger, such as by a factor of at least 5, at least 10, at least 12 or at least 13 larger, than a second axial moment of area of a rectangle that has the same width as the base element and that has the same area as the cross section of the base element and the reinforcement structure in the plane perpendicular to the longitudinal direction, and/or
wherein a height of the reinforcement structure in the height direction amounts to at least 0.1, such as at least a 0.2, at least 0.25, at least 0.5 or at least 1 time a height of the base element in the height direction.

33. Micromechanical beam according to claim 31,
wherein the reinforcement structure comprises at least one ridge that extends parallel to the longitudinal direction,
wherein, for example, an aspect ratio of the height of the ridge in the height direction over the width of the ridge in the width direction is at least 0.1, such as at least 0.2 or at least 0.25,
wherein, for example, the aspect ratio is at least 0.5, at least 1, at least 2.5, at least 3, or at least 3.5,
wherein, for example, the aspect ratio is larger than 2.5.

34. Micromechanical beam according to claim 33,
wherein the ridge forms part of an electrically conducting structure or forms a support for the electrically conducting structure.

35. Micromechanical beam according to claim 33,
wherein the reinforcement structure comprises several ridges extending in parallel to the longitudinal direction and being placed next to each other along the width direction,
wherein, for example, the ridges have a same width in the width direction and/or a same height in the height direction.

36. Micromechanical beam according to claim 35,
wherein neighboring ridges of the reinforcement structure are connected to each other at alternating longitudinal ends to form a meandering structure.

37. Micromechanical beam according to claim 31,
wherein the reinforcement structure is a continuous structure in a plane perpendicular to the height direction that continuously runs from a first end to a second end,
wherein, for example, the first end and/or the second end are located at an end of the reinforcement section that faces towards the fixed end of the micromechanical beam,
wherein, for example, the first end and the second end are located at the same end of the reinforcement section.

38. Micromechanical beam according to claim 31,
wherein the reinforcement structure forms part of an electrically conducting structure or forms a support for the electrically conducting structure,
wherein, for example, the conducting structure provides a continuous path for current flow.

39. Micromechanical beam according to claim 31,
comprising a patterned multi-layer structure,
wherein the patterned multi-layer structure comprises the reinforcement structure,
wherein, for example, the patterned multilayer structure is homogeneously patterned in the height direction.

40. Micromechanical beam according to claim 31,
wherein the reinforcement structure and the base element are materially uniform and integrally joined together.

41. Micromechanical beam according to claim 31,
wherein the reinforcement structure comprises a material that is different from a base material of the base element,
wherein, for example, the reinforcement structure is entirely made from materials that are different from the base material of the base element.

42. Micromechanical beam according to claim 31,
wherein the micromechanical beam comprises an electrically conducting metal structure on top of the reinforcement structure that is galvanically isolated from the reinforcement structure or
wherein the reinforcement structure comprises the electrically conducting metal structure, for example consists of the electrically conducting metal structure,
wherein, for example, the metal structure has two leads that longitudinally extend through the bending section for connection of an electrical power source.

43. Micromechanical beam according to claim 42,
wherein the metal structure has at least two conducting layers placed on top of each other in the height direction that form a thermally active multi-metal structure that is configured to cause bending strain on the beam and/or
wherein the reinforcement structure has been formed by etching the base element using the metal structure as an etch mask.

44. Micromechanical beam according to claim 31,
wherein the beam has a further reinforcement structure that is located in the reinforcement section and that is placed at a further surface of the base element of the beam, the surface and the further surface being parallel to each other and located at opposing sides of the base element in the height direction, and/or
wherein the beam has a readout structure, for example a piezo-resistive readout structure and/or Wheatstone bridge, for measuring mechanical oscillations of the beam in the height direction and the readout structure is located in the bending section of the beam, and/or
wherein the beam has at least one lateral cutout that is located in the bending section.

45. Micromechanical beam according to claim 31,
wherein the beam has two lateral cutouts that are located in the bending section at opposite side surfaces of the beam in the width direction,
wherein the lateral cutouts narrow the width of the beam to at most 0.85, such as at most 0.8, at most 0.75, at most 0.7 or at most 0.67 times a maximum lateral width of the beam in the bending section,
wherein, for example, the width of the beam within the cutouts deviates from a minimum lateral width by less than 20%, such as less than 10% or less than 5% or less than 1%, over a longitudinal length that is at least equal to a longitudinal length of the readout structure.

46. Micromechanical beam according to claim 31,
wherein the beam comprises a drive structure that is configured to excite mechanical oscillations of the beam in the height direction,
wherein the drive structure is located within the reinforcement section,
wherein, for example, the reinforcement structure is formed by a material different from a material of the drive structure.

47. Micromechanical beam according to claim 31,
wherein the beam comprises at least one longitudinal slot that extends over the length of the bending section.

48. Micromechanical beam according to claim 31,
wherein, in the reinforcement section, the beam tapers down along the longitudinal direction by a factor of at least 0.1, such as at least 0.2 or at least 0.25 in the width direction.

49. Method for fabricating a micromechanical beam,
wherein the micromechanical beam extends in a longitudinal direction between a fixed end and a free end,
wherein the beam has a height along a height direction perpendicular to the longitudinal direction, the height being smaller than a width along a width direction,
wherein the beam has a bending section that is located in the longitudinal direction at the fixed end of the beam,
wherein the beam has a reinforcement section that is located in the longitudinal direction between the bending section and the free end,
wherein the beam has a base element and a reinforcement structure located on the base element in the reinforcement section,
wherein the reinforcement structure is configured to increase a flexural stiffness of the beam in the reinforcement section for bending in the height direction,
wherein the method comprises:
providing a base material of the beam;
fabricating a reinforcement structure at a surface of the base material that is perpendicular to a height direction;
fabricating a free standing beam from the base material,
wherein the beam extends along a longitudinal direction between a fixed end and a free end,
wherein the beam has a height along a height direction perpendicular to the longitudinal direction, the height being smaller than a width along a width direction,
wherein the beam has a bending section that is located in the longitudinal direction at the fixed end of the beam and a reinforcement section that is located in the longitudinal direction between the bending section and the free end, wherein the reinforcement structure is located within the reinforcement section, and
wherein the reinforcement structure is configured to increase a flexural stiffness of the beam in the reinforcement section for bending in the height direction.

50. Method according to claim 49,
wherein fabricating the reinforcement structure comprises:
providing a metal structure having leads for connection with an electrical power source on the surface of the base material;
etching the base material parallel to the height direction using the metal structure as an etch mask.
